(19) United States
(12) Patent Application Publication
(10) Pub. No.: US 2007/0105317 A1
(43) Pub. Date: May 10, 2007

(54) Method of manufacturing semiconductor device

(76) Inventor: Kazuaki Nakajima, Kamakura-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 11/378,254

(22) Filed: Mar. 20, 2006

(30) Foreign Application Priority Data
Nov. 9, 2005 (JP) 2005-325024

(51) Int. Cl. H01L 21/336

(52) U.S. Cl. 438/264

(57) ABSTRACT

A method of manufacturing a semiconductor device according to an aspect of the present invention comprises a step of forming a gate insulating layer on a semiconductor substrate, a step of forming a first metal layer on the gate insulating layer, a step of forming a second metal layer including elements for use in work function modulation on the first metal layer, a step of forming a cap layer made of a material having a melting point higher than that of the second metal layer on the second metal layer, and a step of precipitating the elements at an interface between the gate insulating layer and the first metal layer by thermal treatment.

### CROSS-REFERENCE TO RELATED APPLICATIONS

This application is based upon and claims the benefit of priority from prior Japanese Patent Application No. 2005-325024, filed Nov. 9, 2005, the entire contents of which are incorporated herein by reference.

### BACKGROUND OF THE INVENTION

1. Field of the Invention

The present invention relates to a method of manufacturing a metal gate electrode, in particular, a dual metal gate electrode for use in a CMOS circuit.

2. Description of the Related Art

Conventionally, in order to realize the high performance of a MOSFET subject to miniaturization, a metal gate electrode has been proposed. When a metal gate electrode is used, depletion in a gate electrode, which brings about problems on a polysilicon gate electrode, is not brought about, so that an increase of an effective film thickness of a gate insulating film due to depletion can be prevented, which has an advantage for miniaturization.

Here, a threshold voltage of the MOSFET having the metal gate electrode is determined by a high impurity concentration in a channel region and a work function of the metal gate electrode. A work function is set to be greater than or equal to 4.8 eV in a p-channel MOSFET, and is set to be less than or equal to 4.3 eV in an n-channel MOSFET

By the way, existing semiconductor integrated circuits are generally composed of CMOS circuits. Accordingly, in order to form a gate electrode of a CMOS circuit, i.e., a dual metal gate electrode, in a wafer process, it is necessary to establish a film-forming technology for two types of metals, and to have a technology for avoiding the manufacturing processes from being complicated.

However, because there is a great risk from the standpoint of cost in that the film-forming technology for two types of metals is established, a method of manufacturing a work function modulation dual metal gate electrode in accordance with a W-In alloy process has been proposed (for example, refer to Jpn. Pat. Appln. KOKAI Publication No. 2000-315789).

There is the problem in this method that, because In is a low melting point material (melting point: 120° C.), In condenses when W and In are alloyed by heat treatment, which does not allow the alloying to progress well.

### BRIEF SUMMARY OF THE INVENTION

A method of manufacturing a semiconductor device according to an aspect of the present invention, comprises: a step of forming a gate insulating layer on a semiconductor substrate; a step of forming a first metal layer on the gate insulating layer; a step of forming a second metal layer including elements for use in work function modulation on the first metal layer; a step of forming a cap layer made of a material having a melting point higher than that of the second metal layer on the second metal layer; and a step of precipitating the elements at an interface between the gate insulating layer and the first metal layer by thermal treatment.

A method of manufacturing a semiconductor device according to another aspect of the present invention, comprises: a step of forming a gate insulating layer on a semiconductor substrate; a step of forming a first metal layer on the gate insulating layer; a step of forming a second metal layer including elements for use in work function modulation on the first metal layer; a step of forming a cap layer made of a material having a melting point higher than that of the second metal layer on the second metal layer; and a step of forming an alloy layer of the first metal layer and the second metal layer by thermal treatment.

A method of manufacturing a semiconductor device according to another aspect of the present invention, comprises: a step of forming a gate insulating layer on a semiconductor substrate; a step of forming a metal layer on the gate insulating layer; a step of forming a compound layer including elements for use in work function modulation on the metal layer; and a step of precipitating the elements at an interface between the gate insulating layer and the metal layer by thermal treatment.

A method of manufacturing a semiconductor device according to another aspect of the present invention, comprises: a step of forming a gate insulating layer on a semiconductor substrate; a step of forming a metal layer on the gate insulating layer; a step of forming a compound layer including elements for use in work function modulation on the metal layer; and a step of forming an alloy layer of the metal layer and the compound layer by thermal treatment.

A method of manufacturing a semiconductor device according to another aspect of the present invention, comprises: a step of forming a gate insulating layer on a semiconductor substrate; a step of forming a metal layer on the gate insulating layer; a step of forming a semiconductor layer on the metal layer; a step of injecting elements for use in work function modulation into the semiconductor layer; and a step of precipitating the elements at an interface between the gate insulating layer and the metal layer by thermal treatment.

A method of manufacturing a semiconductor device according to another aspect of the present invention, comprises: a step of forming a gate insulating layer on a semiconductor substrate; a step of forming a metal layer on the gate insulating layer; a step of forming a semiconductor layer on the metal layer; a step of injecting elements for use in work function modulation into the semiconductor layer; and a step of forming an alloy layer by making the elements react with the metal layer by thermal treatment.

### BRIEF DESCRIPTION OF THE SEVERAL VIEWS OF THE DRAWING

FIG. 1 is a cross-sectional view showing a process of a method as a reference example;

FIG. 2 is a cross-sectional view showing a process of the method as the reference example;

FIG. 3 is a cross-sectional view showing a process of the method as the reference example;

FIG. 4 is a cross-sectional view showing a process of a method as a first basic configuration;

FIG. 5 is a cross-sectional view showing a process of the method as the first basic configuration;

FIG. 6 is a cross-sectional view showing a process of the method as the first basic configuration;

FIG. 7 is a cross-sectional view showing a process of a method as a second basic configuration;

FIG. 8 is a cross-sectional view showing a process of the method as the second basic configuration;

FIG. 9 is a cross-sectional view showing a process of a method as a third basic configuration;

FIG. 10 is a cross-sectional view showing a process of the method as the third basic configuration;

FIG. 11 is a cross-sectional view showing a process of the method as the third basic configuration;

FIG. 12 is a graph showing the relationship between a gate voltage Vg and a gate capacitance Cg;

FIG. 13 is a plan view showing a device structure as a first embodiment;

FIG. 14 is a cross-sectional view taken along the line XIV-XIV of FIG. 13;

FIG. 15 is a cross-sectional view taken along the line XV-XV of FIG. 13;

FIG. 16 is a cross-sectional view showing a process of a method as the first embodiment;

FIG. 17 is a cross-sectional view showing a process of the method as the first embodiment;

FIG. 18 is a cross-sectional view showing a process of the method as the first embodiment;

FIG. 19 is a cross-sectional view showing a process of the method as the first embodiment;

FIG. 20 is a cross-sectional view showing a process of the method as the first embodiment;

FIG. 21 is a plan view showing a device structure as a second embodiment;

FIG. 22 is a cross-sectional view taken along the line XXII-XXII of FIG. 21;

FIG. 23 is a cross-sectional view taken along the line XXIII-XXIII of FIG. 21;

FIG. 24 is a cross-sectional view showing a process of a method as the second embodiment;

FIG. 25 is a cross-sectional view showing a process of the method as the second embodiment;

FIG. 26 is a cross-sectional view showing a process of the method as the second embodiment;

FIG. 27 is a cross-sectional view showing a process of the method as the second embodiment;

FIG. 28 is a cross-sectional view showing a process of the method as the second embodiment;

FIG. 29 is a cross-sectional view showing a process of a method as a third embodiment;

FIG. 30 is a cross-sectional view taken along the line XXX-XXX of FIG. 29;

FIG. 31 is a cross-sectional view taken along the line XXXI-XXXI of FIG. 29;

FIG. 32 is a cross-sectional view showing a process of a method as the third embodiment;

FIG. 33 is a cross-sectional view showing a process of the method as the third embodiment;

FIG. 34 is a cross-sectional view showing a process of the method as the third embodiment;

FIG. 35 is a cross-sectional view showing a process of the method as the third embodiment;

FIG. 36 is a cross-sectional view showing a process of the method as the third embodiment;

FIG. 37 is a plan view showing a device structure as a fourth embodiment;

FIG. 38 is a cross-sectional view taken along the line XXXVIII-XXXVIII of FIG. 37;

FIG. 39 is a cross-sectional view taken along the line XXXIX-XXXIX of FIG. 37;

FIG. 40 is a cross-sectional view showing a process of a method as the fourth embodiment;

FIG. 41 is a cross-sectional view showing a process of the method as the fourth embodiment;

FIG. 42 is a cross-sectional view showing a process of the method as the fourth embodiment;

FIG. 43 is a cross-sectional view showing a process of the method as the fourth embodiment;

FIG. 44 is a cross-sectional view showing a process of the method as the fourth embodiment;

FIG. 45 is a plan view showing a device structure as a fifth embodiment;

FIG. 46 is a cross-sectional view taken along the line XLVI-XLVI of FIG. 45;

FIG. 47 is a cross-sectional view taken along the line XLVII-XLVII of FIG. 45;

FIG. 48 is a cross-sectional view showing a process of a method as the fifth embodiment;

FIG. 49 is a cross-sectional view showing a process of the method as the fifth embodiment;

FIG. 50 is a cross-sectional view showing a process of the method as the fifth embodiment;

FIG. 51 is a cross-sectional view showing a process of the method as the fifth embodiment;

FIG. 52 is a cross-sectional view showing a process of the method as the fifth embodiment;

FIG. 53 is a cross-sectional view showing a process of the method as the fifth embodiment;

FIG. 54 is a plan view showing a device structure as a sixth embodiment;

FIG. 55 is a cross-sectional view taken along the line LV-LV of FIG. 54;

FIG. 56 is a cross-sectional view taken along the line LVI-LVI of FIG. 54;

FIG. 57 is a cross-sectional view showing a process of a method as the sixth embodiment;

FIG. 58 is a cross-sectional view showing a process of the method as the sixth embodiment;

FIG. 59 is a cross-sectional view showing a process of the method as the sixth embodiment;

FIG. 60 is a cross-sectional view showing a process of the method as the sixth embodiment;

FIG. 61 is a cross-sectional view showing a process of the method as the sixth embodiment;

FIG. 62 is a cross-sectional view showing a process of the method as the sixth embodiment;

FIG. 63 is a plan view showing a device structure as a seventh embodiment;

FIG. 64 is a cross-sectional view taken along the line LXIV-LXIV of FIG. 63;

FIG. 65 is a cross-sectional view taken along the line LXV-LXV of FIG. 63;

FIG. 66 is a cross-sectional view showing a process of a method as the seventh embodiment;

FIG. 67 is a cross-sectional view showing a process of the method as the seventh embodiment;

FIG. 68 is a cross-sectional view showing a process of the method as the seventh embodiment;

FIG. 69 is a cross-sectional view showing a process of the method as the seventh embodiment;

FIG. 70 is a cross-sectional view showing a process of the method as the seventh embodiment;

FIG. 71 is a cross-sectional view showing a process of the method as the seventh embodiment;

FIG. 72 is a cross-sectional view showing a process of the method as the seventh embodiment;

FIG. 73 is a cross-sectional view showing a process of the method as the seventh embodiment;

FIG. 74 is a plan view showing a device structure as an eighth embodiment;

FIG. 75 is a cross-sectional view taken along the line LXXV-LXXV of FIG. 74;

FIG. 76 is a cross-sectional view taken along the line LXXVI-LXXVI of FIG. 74;

FIG. 77 is a cross-sectional view showing a process of a method as the eighth embodiment;

FIG. 78 is a cross-sectional view showing a process of the method as the eighth embodiment;

FIG. 79 is a cross-sectional view showing a process of the method as the eighth embodiment;

FIG. 80 is a plan view showing a CMOS inverter circuit as an application example; and

FIG. 81 is a plan view showing a CMOS inverter circuit as an application example.

### DETAILED DESCRIPTION OF THE INVENTION

A method of manufacturing a semiconductor device according to aspects of the present invention will be described in detail with reference to the drawings.

### 1. BASIC CONFIGURATION

(1) Reference Example

In a CMOS circuit, work function modulation is carried out with respect to, for example, a gate electrode of an n-channel MOSFET. Namely, after metal used as a gate electrode of a p-channel MOSFET is formed, a work function of a part of the metal is modulated by alloying, and the metal is used as a gate electrode of the n-channel MOSFET.

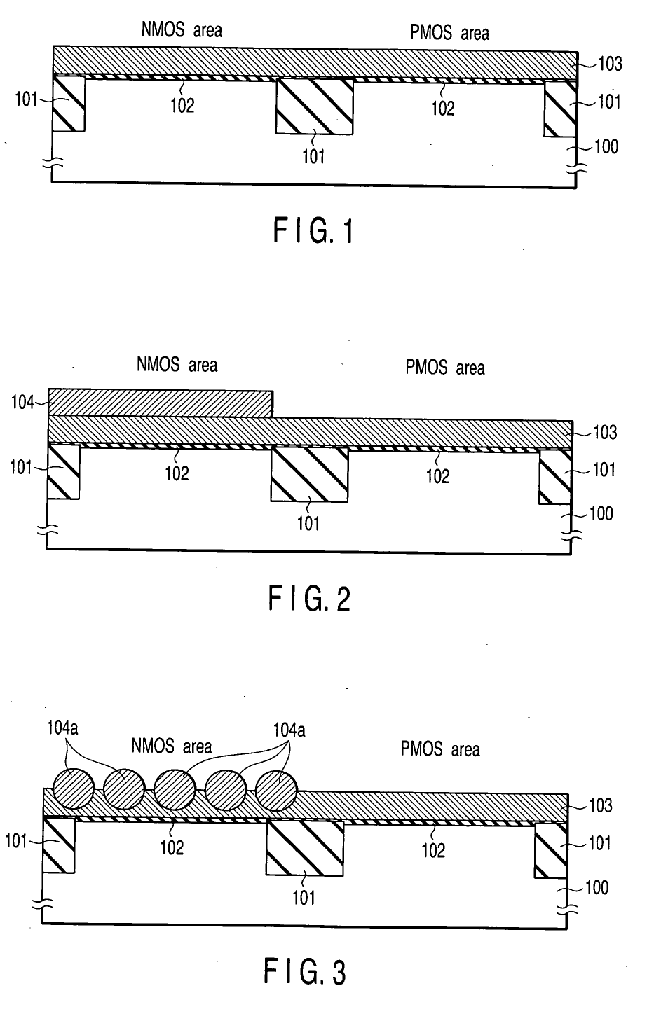

Specifically, first, as shown in FIG. 1, an isolation layer 101 having a shallow trench isolation (STI) structure is formed in a semiconductor substrate 100, and a gate insulating layer 102 is formed on device regions separated by the isolation layer 101. Then, a conductive layer 103 made of tungsten (W) whose work function is 4.9 eV is formed so as to have a thickness of about 50 nm on the gate insulating film 102 by, for example, a CVD method.

Here, in the drawing, an NMOS area denotes an area on which an N-channel MOS transistor is formed, and a PMOS area denotes an area on which a P-channel MOS transistor is formed.

Next, as shown in FIG. 2, a conductive layer 104 made of indium (In) whose work function is 3.9 eV is formed so as to have a thickness of about 20 nm on the conductive layer 103 by, for example, sputtering. Further, the conductive layer 104 in the PMOS area is selectively removed by, for example, photo engraving process (PEP) and reactive ion etching (RIE).

Next, as shown in FIG. 3, the conductive layers 103 and 104 are made to react by carrying out thermal treatment at about 400° C. for about one hour in the nitrogen atmosphere, for example. Namely, a W-In alloy which can be used as a gate electrode of the n-channel MOS transistor is formed by making an alloy of the tungsten and the indium in the NMOS area.

There is the problem in this method that, as shown in FIG. 3, at the time of making an alloy by thermal treatment, indium condenses into a plurality of grains 104a before reacting with tungsten because a melting point of indium is low.

(2) First Basic Configuration

A first basic configuration relates to a method of preventing a low melting point material having a possibility of condensing from condensing by holding the low melting point material between materials having a higher melting point.

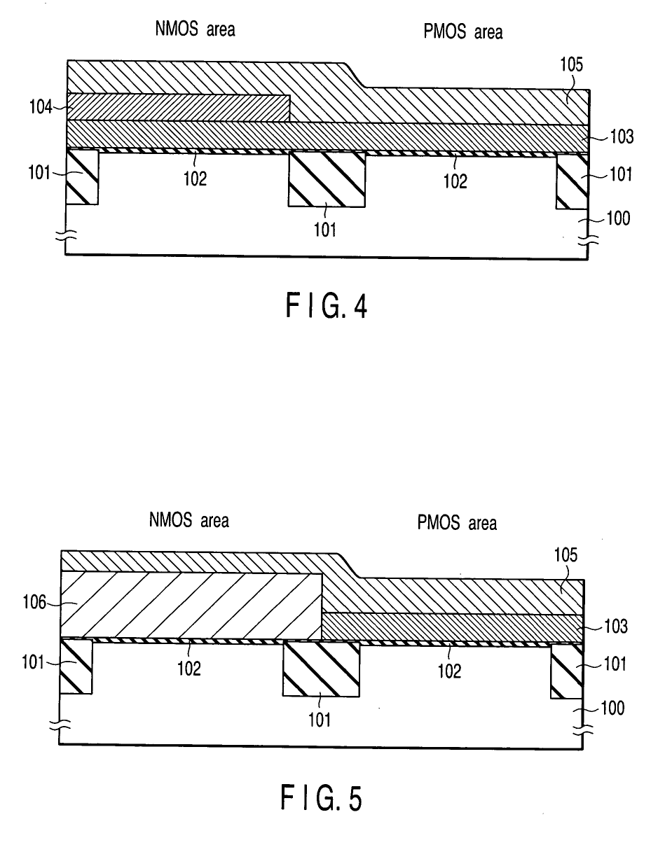

Specifically, first, as shown in FIG. 4, an isolation layer 101 having an STI structure is formed in a semiconductor substrate 100, and a gate insulating layer 102 is formed on device regions separated by the isolation layer 101. Then, a conductive layer 103 made of tungsten (W) whose work function is 4.9 eV is formed so as to have a thickness of about 50 nm on the gate insulating film 102 by, for example, a CVD method.

Thereafter, a conductive layer 104 made of indium (In) whose work function is 3.9 eV is formed so as to have a thickness of about 20 nm on the conductive layer 103 by, for example, sputtering. Further, the conductive layer 104 in the PMOS area is selectively removed by, for example, PEP and RIE.

Further, a cap layer 105 made of tungsten (W) is formed so as to have a thickness of about 100 nm on the conductive layers 103 and 104 by, for example, a CVD method. At this point in time, the NMOS area is made to be a laminated structure of tungsten/indium/tungsten in which the conductive layer 104 is held between the conductive layer 103 and the cap layer 105.

Next, as shown in FIG. 5, the conductive layers 103 and 104 are made to react by carrying out thermal treatment at about 400° C. for about one hour in the nitrogen atmosphere, for example. Namely, a W-In alloy layer 106 which can be used as a gate electrode of the n-channel MOS transistor is formed by making an alloy of the tungsten and the indium in the NMOS area.

At that time, because the indium is covered with the tungsten serving as the cap layer 105, the indium does not condense and reacts with the tungsten.

Note that the work function modulation can be carried out by not only alloying as described above, but also precipitating a material with a low work function at an interface between the gate insulating layer 102 and the conductive layer 103.

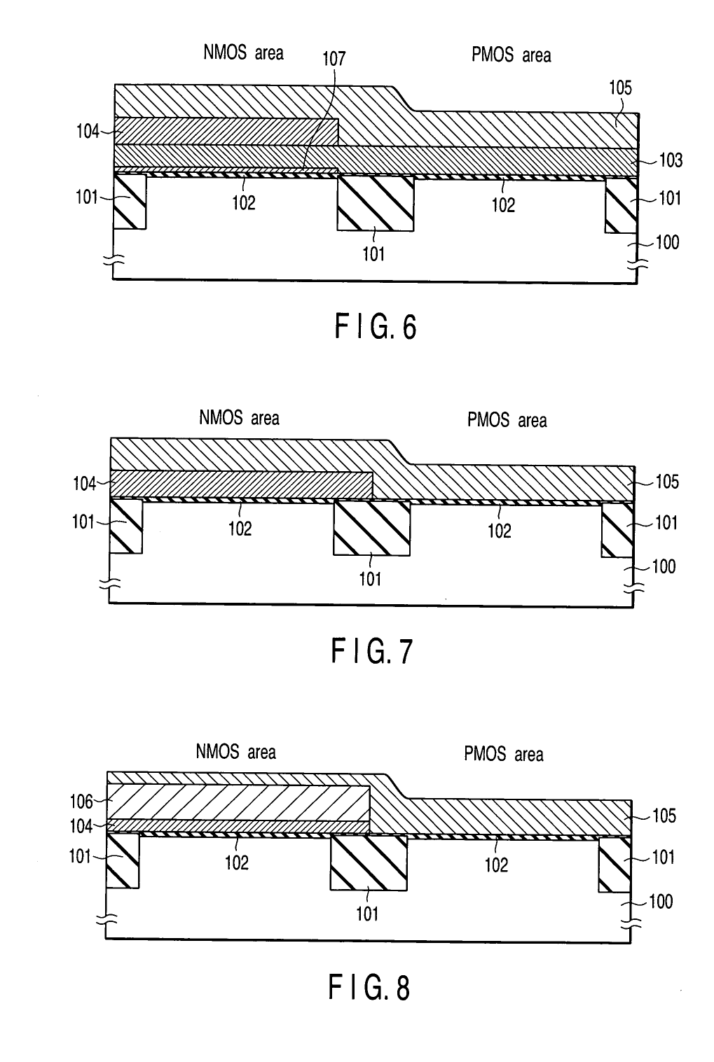

In this case, as shown in FIG. 6, a precipitate layer 107 is formed by precipitating the indium configuring the conductive layer 104 in the NMOS area at the interface between the gate insulating layer 102 and the conductive layer 103 via a grain boundary of the tungsten configuring the conductive layer 103 by thermal treatment in the nitrogen atmosphere.

At this time as well, because the indium is covered with the tungsten serving as the cap layer 105, the indium does not condense, and is precipitated at the interface between the gate insulating layer 102 and the conductive layer 103.

(3) Second Basic Configuration

A second basic configuration relates to a method of preventing a melting point material having a possibility of condensing from condensing by covering the low melting point material with material having a higher melting point.

Specifically, first, as shown in FIG. 7, an isolation layer 101 having an STI structure is formed in a semiconductor substrate 100, and a gate insulating layer 102 is formed on device regions separated by the isolation layer 101.

Further, a conductive layer 104 made of indium (In) whose work function is 3.9 eV is formed so as to have a thickness of about 20 nm on the gate insulating layer 102 by, for example, sputtering. Further, the conductive layer 104 in the PMOS area is selectively removed by, for example, PEP and RIE.

Thereafter, a cap layer 105 made of tungsten (W) whose work function is 4.9 eV is formed so as to have a thickness of about 100 nm on the gate insulating layer 102 and the conductive layer 104 by, for example, a CVD method. At this point in time, the NMOS area is made to be a laminated structure of tungsten/indium/tungsten in which the conductive layer 104 is covered with the cap layer 105.

Next, as shown in FIG. 8, the conductive layer 104 and the cap layer 105 are made to react with each other by carrying out thermal treatment at about 400° C. for about one hour in the nitrogen atmosphere, for example. Namely, a W-In alloy layer 106 which can be used as a gate electrode of the n-channel MOS transistor is formed by making an alloy of the tungsten and the indium in the NMOS area.

At this time, because the indium is covered with the tungsten serving as the cap layer 105, the indium does not condense and reacts with the tungsten.

Because, in the second basic configuration, the indium directly contacts the gate insulating layer 102, the conditions thereof are set such that the indium is not peeled from the gate insulating film 102 at the time of thermal treatment.

(4) Third Basic Configuration

A third basic configuration relates to a method of preventing a metal from condensing by making a low melting point material having a possibility of condensing into a compound having a higher melting point.

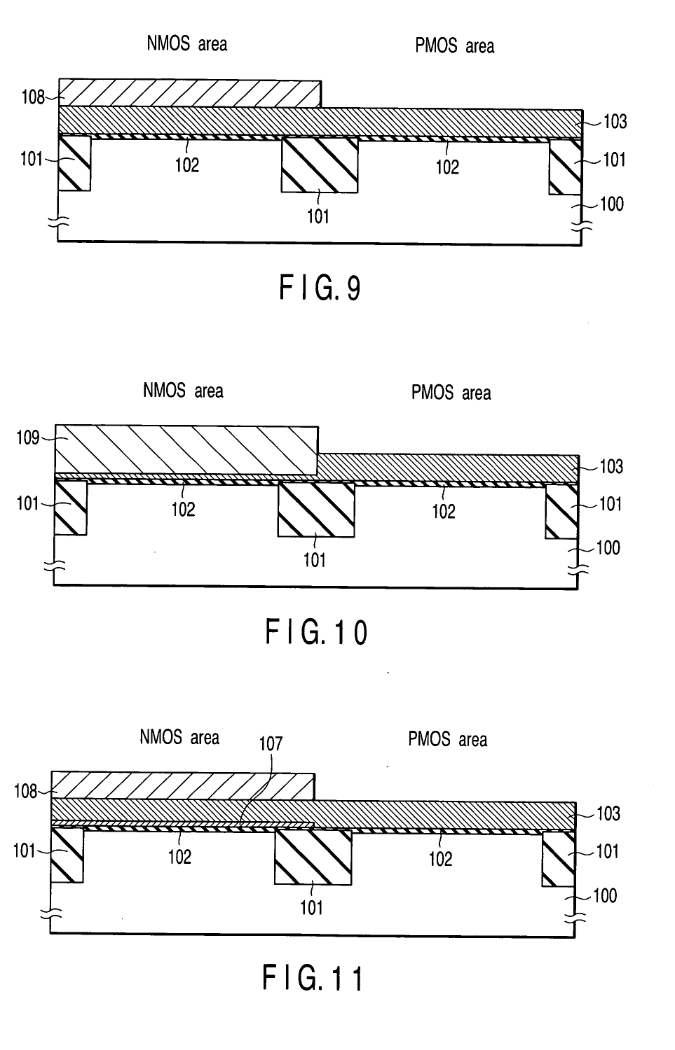

Specifically, first, as shown in FIG. 9, an isolation layer 101 having an STI structure is formed in a semiconductor substrate 100, and a gate insulating layer 102 is formed on device regions separated by the isolation layer 101. Further, a conductive layer 103 made of tungsten (W) whose work function is 4.9 eV is formed so as to have a thickness of about 50 nm on the gate insulating layer 102.

In addition, a conductive layer 108 made of a compound including indium (In) whose work function is 3.9 eV, for example, a compound semiconductor (InP, InSp, or the like) is formed so as to have a thickness of about 20 nm on the conductive layer 103. Further, the conductive layer 108 in the PMOS area is selectively removed by, for example, PEP and RIE.

Next, as shown in FIG. 10, the conductive layers 103 and 108 are made to react with each other by carrying out thermal treatment at about 400° C. for about one hour in the nitrogen atmosphere, for example.

For example, when InP is used as a compound, the melting point of InP is about 1080° C., which is sufficiently higher than the melting point of In (120° C.). Therefore, a W-In-P alloy layer 109 which can be used as a gate electrode of the n-channel MOS transistor is formed without bringing about condensation.

For example, when InSb is used as a compound, the melting point of InSb is about 580° C., which is sufficiently higher than the melting point of In. Therefore, the W-In-P alloy layer 109 which can be used as a gate electrode of the n-channel MOS transistor is formed without bringing about condensation.

Note that, as described in the first basic configuration, work function modulation can be carried out by not only alloying, but also precipitating a material with a low work function at an interface between the gate insulating layer 102 and the conductive layer 103. Here, the indium in the conductive layer 108 of FIG. 9 may be precipitated.

In this case, as shown in FIG. 11, a precipitate layer 107 is formed by precipitating the indium in the conductive layer 108 at the interface between the gate insulating layer 102 and the conductive layer 103 via a grain boundary of the tungsten configuring the conductive layer 103 by thermal treatment in the nitrogen atmosphere.

At this time as well, because the conductive layer 108 is composed of a compound having a high melting point, the conductive layer 108 does not condense and is precipitated at the interface between the gate insulating layer 102 and the conductive layer 103. The third basic configuration may be combined with the first basic configuration. Namely, a conductive layer serving as a cap layer may be formed on a compound.

### 2. EXPERIMENTAL RESULTS OF WORK FUNCTION MODULATION

Experimental results of work function modulation will be described.

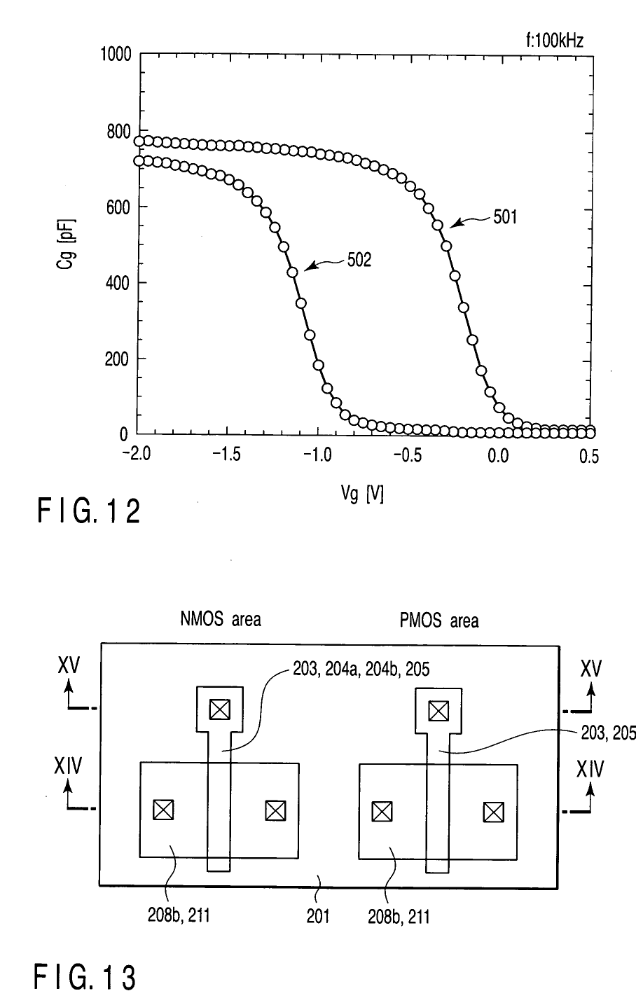

FIG. 12 shows the relationship between a gate capacitance Cg and a gate voltage Vg of a MOS capacitor.

A curved line 501 is the Cg-Vg characteristic of a MOS capacitor (sample 1) in which the gate electrode is made of tungsten (W), and a curved line 502 is the Cg-Vg characteristic of a MOS capacitor (sample 2) in which a gate electrode is composed of tungsten (W)/indium (In)/tungsten (W).

Note that thermal treatment at bout 400° C. for one hour have been carried out onto both of the samples 1 and 2 in the nitrogen atmosphere at the time of forming the gate electrodes.

A flat band voltage Vfb of the sample 1 is −0.02V, and on the basis thereof, the work function of the gate electrode is calculated to be 4.9 eV. Further, a flat band voltage Vfb of the sample 2 is −0.92V, and on the basis thereof, the work function of the gate electrode of is calculated to be 4.0 eV.

In this way, the main reason for that the work function of the sample 2 is made little is due to the indium being precipitated between the gate insulating layer and the tungsten layer by thermal treatment.

### 3. MATERIAL EXAMPLES

Material examples which are applied to the methods of manufacturing a metal gate electrode by the work function modulation in accordance with the examples of the present invention will be described.

With respect to the gate electrode of the p-channel MOS transistor, the material is selected from among metals such as W, Pd, Pt, Ni, Co, Rh, Ir, Nb, Mo, Ta, Sb, Bi, Er and Ti, alloys including at least one of the metals, and nitrides, carbides, or silicon nitrides of the metals.

A material for use in work function modulation is selected from among metals such as In, Ga, Tl, Sb and Bi, alloys including at least one of the metals, and the like. The material for use in work function modulation may be In and Ga such as InP, InSb, GaInSb and GaSb, or may be a III-V compound semiconductor including the both of those.

With respect to the cap layer used for preventing the condensation of a metal, the material is selected from among metals such as W, Pd, Pt, Ni, Co, Rh, Ir, Nb, Mo, Ta, Sb, Bi, Er and Ti, alloys including at least one of the metals, and nitrides, carbides, or silicon nitrides of the metals.

The cap layer can be composed of a material having a barrier function which does not contribute to the reaction with a material for use in work function modulation, such as, a titanium nitride, a tantalum nitride, a tungsten nitride, a titanium silicon nitride (TiSiN), a titanium carbide and a tungsten carbide.

The material as a gate electrode of the p-channel MOS transistor and the material as a cap layer may be the same, or may be different from each other.

### 4. EMBODIMENTS

Next, some embodiments as best modes will be described.

### (1) First Embodiment

A first embodiment relates to a method of manufacturing a dual metal gate electrode based on the first basic configuration, and is an example in which work function modulation is carried out by precipitating a material with a low work function directly on a gate insulating layer.

A. Device Structure

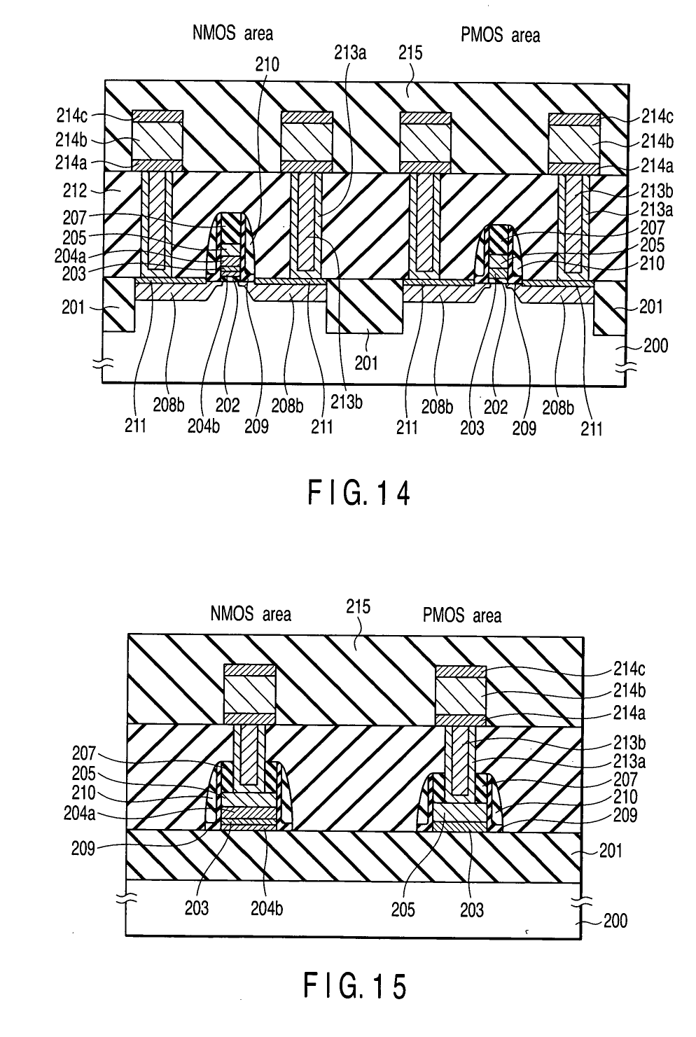

FIG. 13 is a plan view of a CMOS circuit which is formed by the method according to the first embodiment. FIG. 14 is a cross-sectional view taken along the line XIV-XIV of FIG. 13, and FIG. 15 is a cross-sectional view taken along the line XV-XV of FIG. 13.

An isolation layer 201 having an STI structure is arranged in a semiconductor substrate 200. As a consequence, a PMOS area in which a p-channel MOS transistor is formed and an NMOS area in which an n-channel MOS transistor is formed are formed.

The p-channel MOS transistor is configured by source/drain diffusion layers 208b, a gate insulating layer 202 on a channel between the source/drain diffusion layers 208b, and a gate electrode on the gate insulating layer 202.

The gate electrode is configured by a ruthenium (Ru) layer 203 on the gate insulating layer 202 and a ruthenium layer 205 on the ruthenium layer 203. Here, the ruthenium layers 203 and 205 are layers divided from the viewpoint of the process, and the both are unified as a structure.

A silicon nitride layer 207 serving as a mask material is arranged on the ruthenium layer 205. Further, silicon nitride layers 209 and silicon oxide layers 210 serving as sidewalls are arranged at sidewall portions of the gate electrode.

Nickel silicide layers 211 are formed on the surface regions of the source/drain diffusion layers 208b.

Electrodes composed of titanium nitride layers 214a and 214c, and an aluminum layer 214b are connected to the nickel silicide layers 211 and the ruthenium layer 205 serving as a gate electrode via titanium/titanium nitride 213a serving as barrier metals and tungsten 213b serving as contact plugs.

The n-channel MOS transistor is configured by source/drain diffusion layers 208b, a gate insulating layer 202 on a channel between the source/drain diffusion layers 208b, and a gate electrode on the gate insulating layer 202.

The gate electrode is composed of an indium (Ru) precipitate layer 204b on the gate insulating layer 202, a ruthenium layer 203 on the indium precipitate layer 204b, an InSb layer 204a on the ruthenium layer 203, and a ruthenium layer 205 on the InSb layer 204a. Here, the ruthenium layers 203 and 205 are the same as the ruthenium layers 203 and 205 configuring the gate electrode of the p-channel MOS transistor.

A silicon nitride layer 207 serving as a mask material is arranged on the ruthenium layer 205. Further, silicon nitride layers 209 and silicon oxide layers 210 serving as sidewalls are arranged at sidewall portions of the gate electrode.

Nickel silicide layers 211 are formed on the surface regions of the source/drain diffusion layers 208b.

Electrodes composed of titanium nitride layers 214a and 214c, and a aluminum layer 214b are connected to the nickel silicide layers 211 and the ruthenium layer 205 serving as a gate electrode via titanium/titanium nitride 213a serving as barrier metals and tungsten 213b serving as contact plugs.

Both of the p-channel MOS transistor and the n-channel MOS transistor are covered with the silicon oxide layers 212 and 215 serving as interlayer insulating layers.

B. Method of Manufacturing Semiconductor Device

A method of manufacturing a dual metal gate electrode by work function modulation according to the first embodiment will be described.

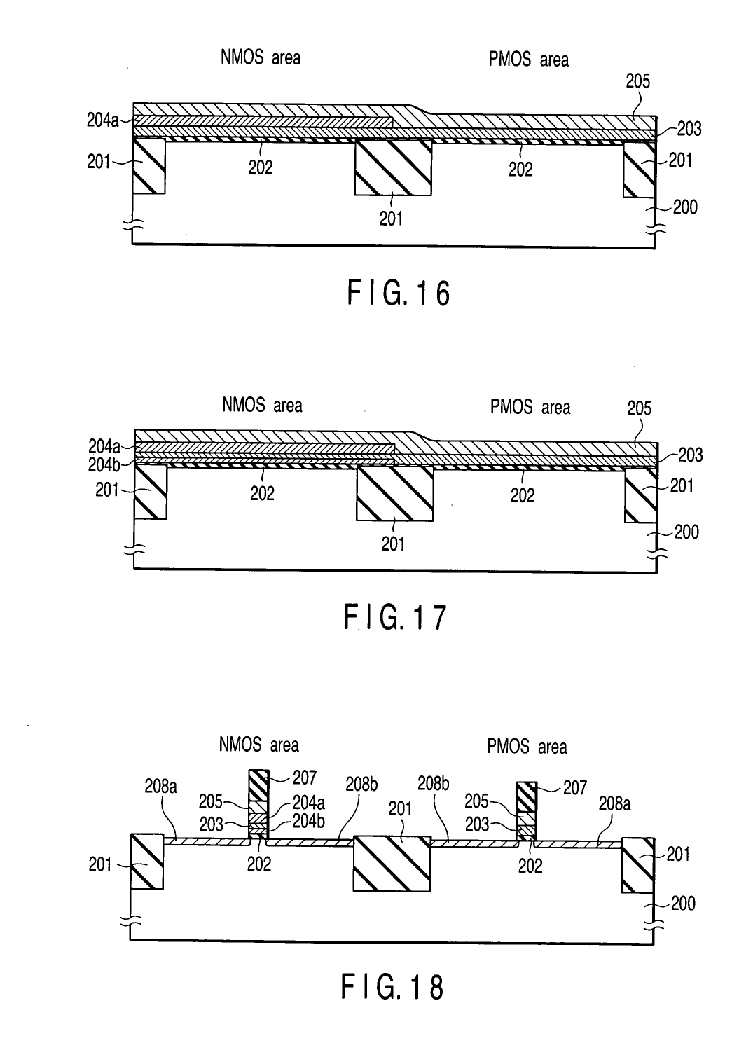

First, as shown in FIG. 16, an isolation layer 201 having an STI structure is formed in a semiconductor substrate 200, and a gate insulating layer 202 is formed on device regions separated by the isolation layer 201 by a thermal oxidation method. Further, a ruthenium layer 203 is formed so as to have a thickness of about 60 nm on the gate insulating layer 202 by, for example, a CVD method using an organic source.

Thereafter, an InSb layer 204a is formed so as to have a thickness of about 20 nm on the ruthenium layer 203 by, for example, sputtering. Further, the InSb layer 204a is selectively removed by, for example, PEP and RIE.

In addition, a ruthenium layer 205 is formed so as to have a thickness of about 20 nm on the ruthenium layer 203 and the InSb layer 204a by, for example, a CVD method. At this point in time, the NMOS area is made to be a laminated structure of Ru/InSb/Ru in which the InSb layer 204a is held between the ruthenium layers 203 and 205.

Next, as shown in FIG. 17, thermal treatment at about 500° C. for about thirty seconds is carried out in the nitrogen atmosphere, for example. As a result, In in the InSb layer 204a diffuses via a grain boundary of the ruthenium layer 203, and is precipitated at an interface between the gate insulating layer 202 and the ruthenium layer 203 to become an indium precipitate layer 204b.

Next, as shown in FIG. 18, a silicon nitride layer 207 is formed on the ruthenium layer 205 by, for example, a CVD method. Patterning is carried out the silicon nitride layer 207 by PEP and RIE, and moreover, the ruthenium layers 203 and 205, the InSb layer 204a, the indium precipitate layer 204b, and the gate insulating layer 202 are etched by RIE using the silicon nitride layer 207 as a mask.

As a result, a metal gate electrode of a p-channel MOS transistor made of Ru is formed in the PMOS area, and a metal gate electrode of an n-channel MOS transistor composed of a lamination layer of In/Ru/InSb/Ru is formed in the NMOS area.

Thereafter, extension diffusion layers 208a are formed, with the metal gate electrodes being as masks, by carrying out ion implantation of a p-type impurity (for example, B, BF₂, or the like) into the PMOS area in a self-alignment manner, and by carrying out ion implantation of an n-type impurity (for example, P, As, or the like) into the NMOS area in a self-alignment manner.

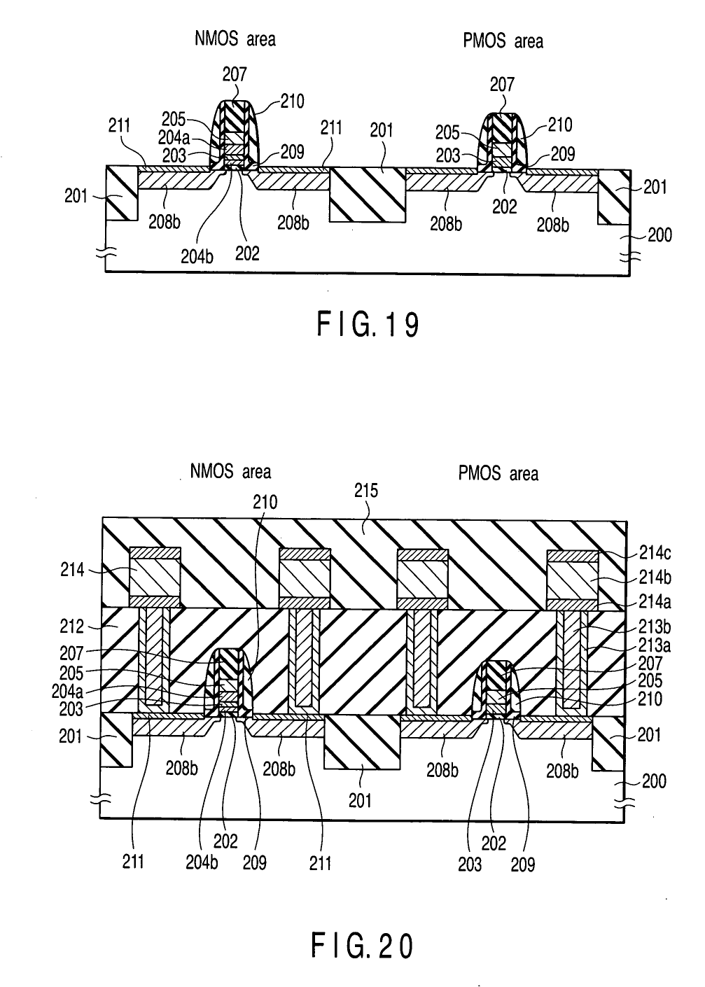

Next, as shown in FIG. 19, silicon nitride layers 209 and silicon oxide layers 210 are formed by, for example, a CVD method. In addition, the silicon nitride layers 209 and the silicon oxide layers 210 are etched by RIE, and those are made to remain as sidewalls at the sidewall portions of the metal gate electrodes.

Then, source/drain layers 208b are formed, with the metal gate electrodes and the sidewalls being as masks, by carrying out ion implantation of a p-type impurity (for example, B, BF₂, or the like) into the PMOS area in a self-alignment manner, and by carrying out ion implantation of an n-type impurity (for example, P, As, or the like) into the NMOS area in a self-alignment manner.

Nickel (Ni) layers are formed so as to have a thickness of about 10 nm on the source/drain layers 208b by, for example, sputtering. Then, silicon (Si) in the source/drain layers 208b and nickel (Ni) in the nickel layers are made to react with each other by carrying out thermal treatment at about 350° C. for about thirty seconds.

Thereafter, unreacted nickel layers are removed by using, for example, a compound liquid of sulfuric acid and hydrogen peroxide, and thermal treatment is carried out at about 500° C. for about thirty seconds again, whereby the nickel silicide layers 211 are formed.

Next, as shown in FIG. 20, a silicon oxide layer 212 covering the p-channel MOS transistor and the n-channel MOS transistor is formed by, for example, a CVD method. Further, the surface of the silicon oxide layer 212 is planarized by, for example, a chemical mechanical grinding (CMP) method.

Then, after contact holes reaching the source/drain diffusion layers 208b are formed at the silicon oxide layer 212, titanium/titanium nitride 213a serving as barrier metals and tungsten 213b serving as contact plugs are formed in the contact holes.

Electrodes composed of titanium nitride layers 214a and 214c, and an aluminum layer 214b are formed on the silicon oxide layer 212, and a silicon oxide layer 215 covering those electrodes is formed on the silicon oxide layer 212.

The gate electrode of the p-channel MOS transistor formed by such a method is composed of Ru whose work function is 5.0 eV.

In addition, the gate electrode of the n-channel MOS transistor is composed of a lamination layer of In/Ru/InSb/Ru. Here, a threshold value of the n-channel MOS transistor depends on a work function of In precipitated directly on the gate insulating layer 202, and the value becomes 3.9 eV, so that work function modulation is appropriately carried out.

Note that, as the gate insulating layer 202, not only silicon oxide, but also an oxide, a nitride, or an oxynitride of Hf, Zr, Ti, Ta, Al, Sr, Y, La and the like, or an oxide, a nitride, or an oxynitride as a compound of those elements and silicon can be used. For example, a high dielectric constant material such as a zirconium oxide and a hafnium oxide is used as the gate insulating layer 202.

C. Summary

In accordance with the first embodiment, in the method of manufacturing a dual metal gate electrode, a metal is prevented from condensing, so that a material with a low work function is precipitated directly on the gate insulating layer, and work function modulation can be exactly carried out.

### (2) Second Embodiment

A second embodiment relates to a method of manufacturing a dual metal gate electrode based on the first basic configuration, and is an example in which work function modulation is carried out by alloying.

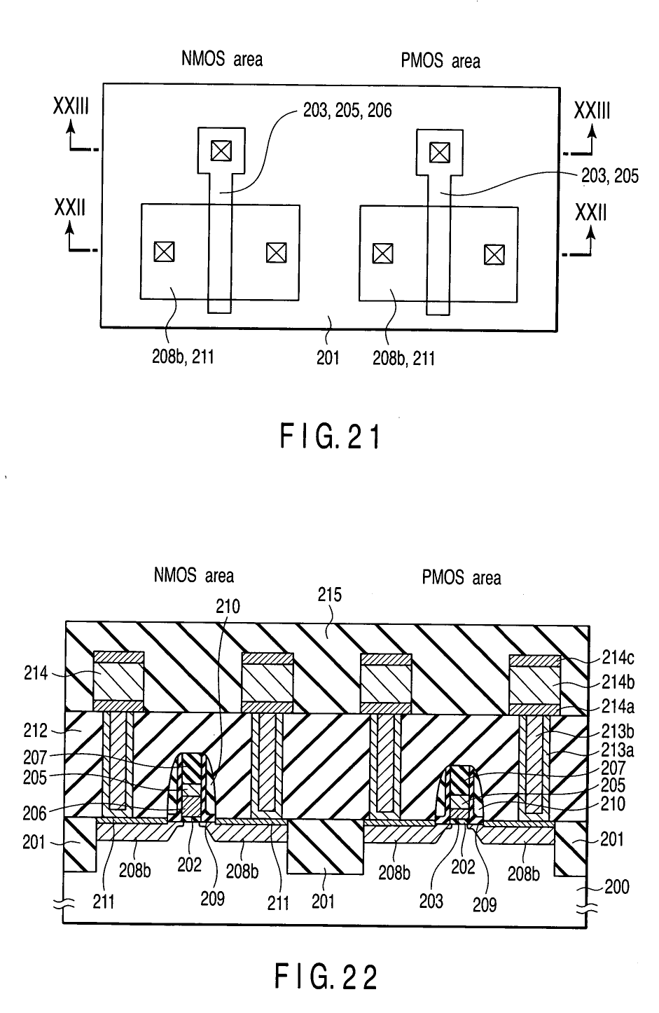

A. Device Structure FIG. 21 is a plan view of a CMOS circuit which is formed by the method according to the second embodiment. FIG. 22 is a cross-sectional view taken along the line XXII-XXII of FIG. 21, and FIG. 23 is a cross-sectional view taken along the line XXIII-XXIII of FIG. 21.

An isolation layer 201 having an STI structure is arranged in a semiconductor substrate 200. As a consequence, a PMOS area in which a p-channel MOS transistor is formed and an NMOS area in which an n-channel MOS transistor is formed are formed.

The p-channel MOS transistor is configured by source/drain diffusion layers 208b, a gate insulating layer 202 on a channel between the source/drain diffusion layers 208b, and a gate electrode on the gate insulating layer 202.

The gate electrode is configured by a ruthenium (Ru) layer 203 on the gate insulating layer 202 and a ruthenium layer 205 on the ruthenium layer 203. Here, both of the ruthenium layers 203 and 205 are unified as a structure in the same way as in the first embodiment.

A silicon nitride layer 207 serving as a mask material is arranged on the ruthenium layer 205. Further, silicon nitride layers 209 and silicon oxide layers 210 serving as sidewalls are arranged at sidewall portions of the gate electrode.

Nickel silicide layers 211 are formed on the surface regions of the source/drain diffusion layers 208b.

Electrodes composed of titanium nitride layers 214a and 214c, and an aluminum layer 214b are connected to the nickel silicide layers 211 and the ruthenium layer 205 serving as a gate electrode titanium/titanium nitride 213a serving as barrier metals and tungsten 213b serving as contact plugs.

The n-channel MOS transistor is configured by source/drain diffusion layers 208b, a gate insulating layer 202 on a channel between the source/drain diffusion layers 208b, and a gate electrode on the gate insulating layer 202.

The gate electrode is configured by an InRuSb layer 206 serving as an alloy layer on the gate insulating layer 202, and a ruthenium layer 205 on the InRuSb layer 206. Here, the ruthenium layer 205 is the same as the ruthenium layer 205 configuring the gate electrode of the p-channel MOS transistor.

A silicon nitride layer 207 serving as a mask material is arranged on the ruthenium layer 205. Further, silicon nitride layers 209 and silicon oxide layers 210 serving as sidewalls are arranged at the sidewall portions of the gate electrode.

Nickel silicide layers 211 are formed on the surface regions of the source/drain diffusion layers 208b.

Electrodes composed of titanium nitride layers 214a and 214c, and an aluminum layer 214b are connected to the nickel silicide layers 211 and the ruthenium layer 205 serving as a gate electrode via titanium/titanium nitride 213a serving as barrier metals and tungsten 213b serving as contact plugs.

Both of the p-channel MOS transistor and the n-channel MOS transistor are covered with the silicon oxide layers 212 and 215 serving as interlayer insulating layers.

B. Method of Manufacturing Semiconductor Device

A method of manufacturing a dual metal gate electrode by work function modulation according to the second embodiment will be described.

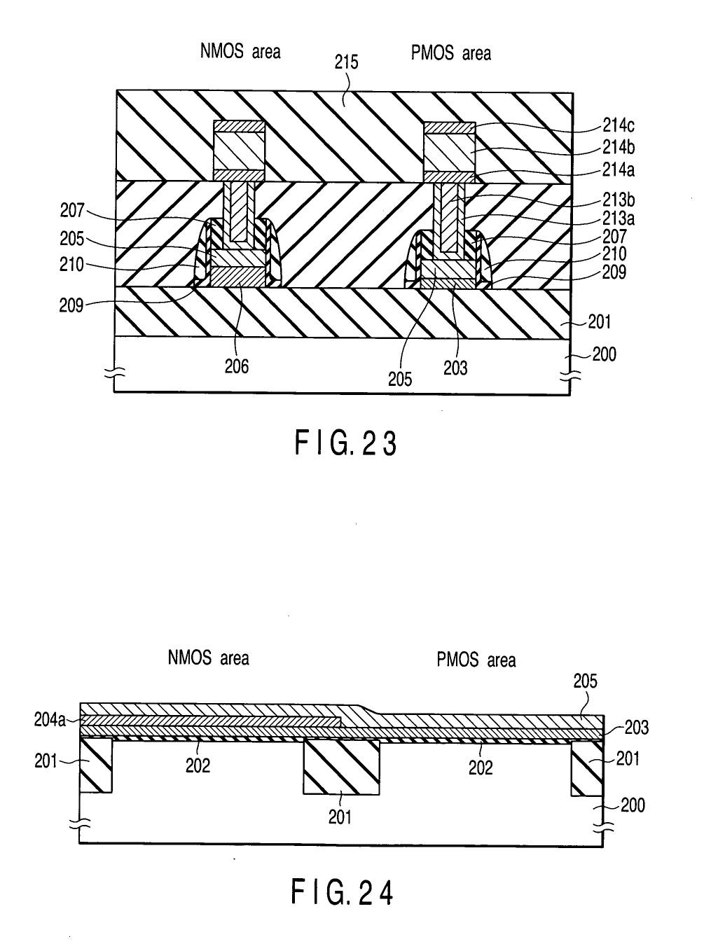

First, as shown in FIG. 24, an isolation layer 201 having an STI structure is formed in a semiconductor substrate 200, and a gate insulating layer 202 is formed by a thermal oxidation method on device regions separated by the isolation layer 201. Further, a ruthenium layer 203 is formed so as to have a thickness of about 60 nm on the gate insulating layer 202 by, for example, a CVD method using an organic source.

Thereafter, an InSb layer 204a is formed so as to have a thickness of about 20 nm on the ruthenium layer 203 by, for example, sputtering. Further, the InSb layer 204a in the PMOS area is selectively removed by, for example, PEP and RIE.

Further, a ruthenium layer 205 is formed so as to have a thickness of about 20 nm on the ruthenium layer 203 and the InSb layer 204a by, for example, a CVD method using an organic source. At this point in time, the NMOS area is made to be a laminated structure of Ru/InSb/Ru in which the InSb layer 204a is held between the ruthenium layers 203 and 205.

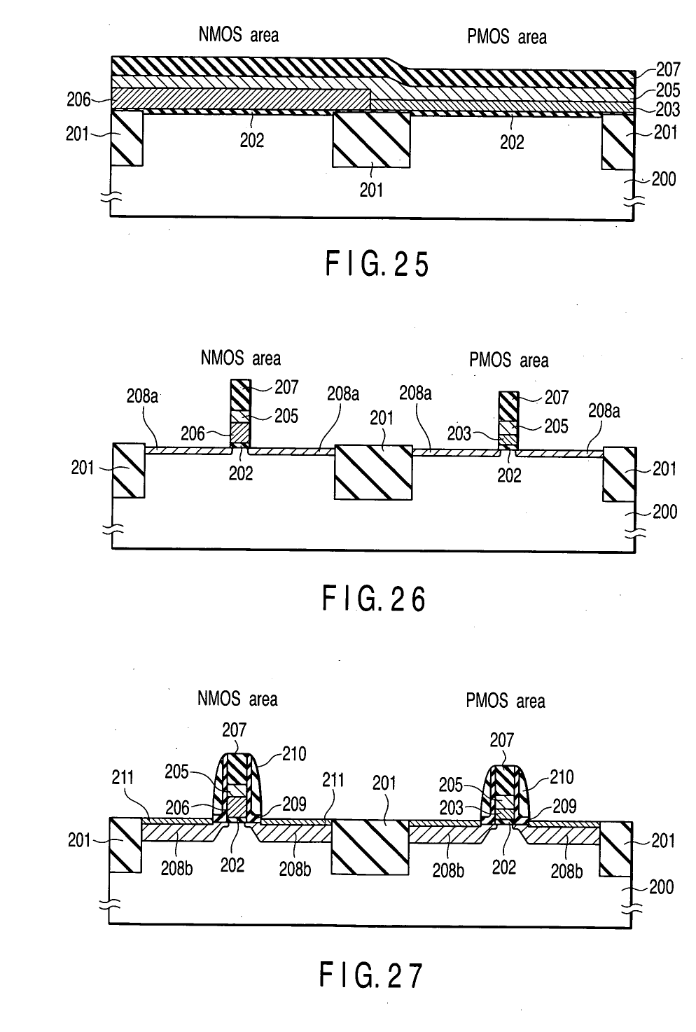

Next, as shown in FIG. 25, thermal treatment at about 400° C. for about one hour is carried out in the nitrogen atmosphere, for example. As a result, the InSb layer 204a chemically reacts with the ruthenium layers 203 and 205 to become an InRuSb layer 206 serving as an alloy layer. Here, the thermal treatment is carried out under the conditions that the InRuSb layer 206 comes down to the gate insulating layer 202.

Next, as shown in FIG. 26, a silicon nitride layer 207 is formed on the ruthenium layer 205 by, for example, a CVD method. Patterning is carried out the silicon nitride layer 207 by PEP and RIE, and moreover, the ruthenium layers 203 and 205, the InRuSb layer 206, and the gate insulating layer 202 are etched with the silicon nitride layer 207 being as a mask by RIE.

As a result, a metal gate electrode of a p-channel MOS transistor made of Ru is formed in the PMOS area, and a metal gate electrode of an n-channel MOS transistor composed of a lamination layer of InRuSb/Ru is formed in the NMOS area.

Thereafter, extension diffusion layers 208a are formed, with the metal gate electrodes being as masks, by carrying out ion implantation of a p-type impurity (for example, B, BF₂, or the like) into the PMOS area in a self-alignment manner, and by carrying out ion implantation of an n-type impurity (for example, P, As, or the like) into the NMOS area in a self-alignment manner.

Next, as shown in FIG. 27, silicon nitride layers 209 and silicon oxide layers 210 are formed by, for example, a CVD method. Further, the silicon nitride layers 209 and the silicon oxide layers 210 are etched by RIE, and those are made to remain as sidewalls at the sidewall portions of the metal gate electrodes.

Thereafter, source/drain layers 208b are formed, with the metal gate electrodes and the sidewalls being as masks, by carrying out ion implantation of a p-type impurity (for example, B, BF₂, or the like) into the PMOS area in a self-alignment manner, and by carrying out ion implantation of an n-type impurity (for example, P, As, or the like) into the NMOS area in a self-alignment manner.

In addition, nickel (Ni) layers are formed so as to have a thickness of about 10 nm on the source/drain layers 208b by, for example, sputtering. Then, silicon (Si) in the source/drain layers 208b and nickel (Ni) in the nickel layers are made to react with each other by carrying out thermal treatment at about 350° C. for about thirty seconds.

Thereafter, unreacted nickel layers are removed by using, for example, a compound liquid of sulfuric acid and hydrogen peroxide, and nickel silicide layers 211 are formed by carrying out thermal treatment at about 500° C. for about thirty seconds.

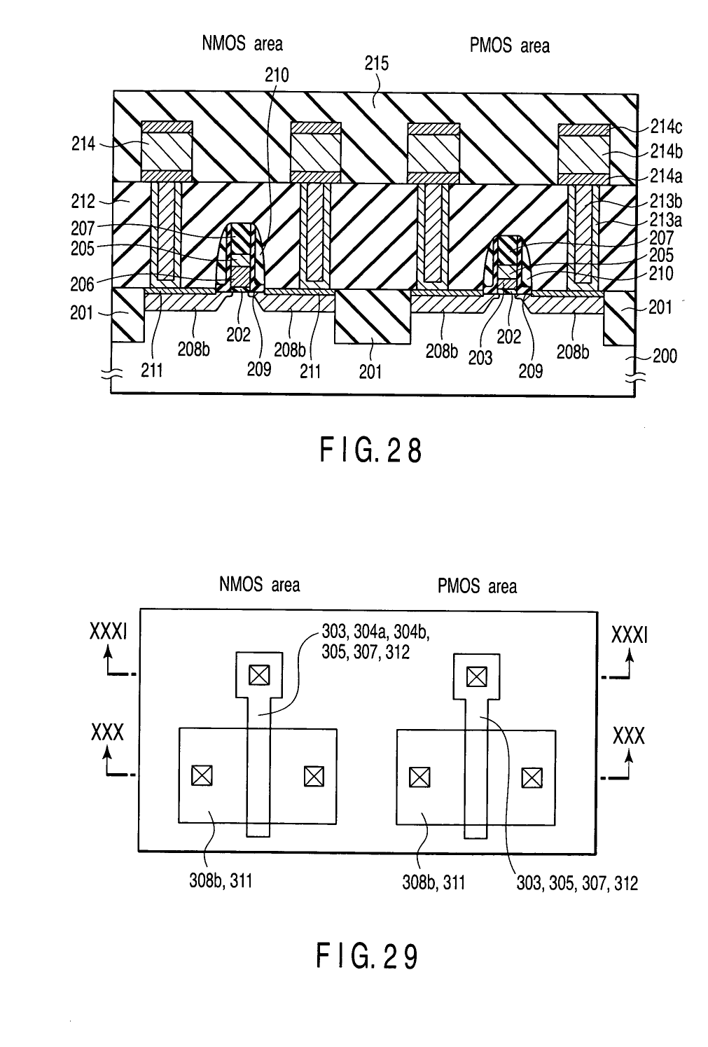

Next, as shown in FIG. 28, a silicon oxide layer 212 covering the p-channel MOS transistor and the n-channel MOS transistor is formed by, for example, a CVD method. Further, the surface of the silicon oxide layer 212 is planarized by, for example, a chemical mechanical grinding (CMP) method.

After contact holes coming down to the source/drain diffusion layers 208b are formed at the silicon oxide layer 212, titanium/titanium nitride 213a serving as barrier metals and tungsten 213b serving as contact plugs are formed in the contact holes.

Electrodes composed of titanium nitride layers 214a and 214c, and an aluminum layer 214b are formed on the silicon oxide layer 212, and a silicon oxide layer 215 covering those electrodes is formed on the silicon oxide layer 212.

The gate electrode of the p-channel MOS transistor formed by such a method is composed of Ru whose work function is 5.0 eV.

Further, the gate electrode of the n-channel MOS transistor is composed of a laminated structure of InRuSb/Ru. Here, a threshold value of the n-channel MOS transistor depends on a work function of InRuSb/Ru directly on the gate insulating layer 202, and the value becomes 4.1 eV, so that work function modulation can be appropriately carried out.

Note that, as the gate insulating layer 202, not only silicon oxide, but also an oxide, a nitride, or an oxynitride of Hf, Zr, Ti, Ta, Al, Sr, Y, La and the like, or an oxide, a nitride, or an oxynitride as a compound of those elements and silicon can be used in the same way as in the first embodiment. For example, a high dielectric constant material such as a zirconium oxide and a hafnium oxide is used as the gate insulating layer 202.

C. Summary

In accordance with the second embodiment, in the method of manufacturing a dual metal gate electrode, a metal is prevented from condensing, so that an alloy layer with a low work function is formed directly on the gate insulating layer, and work function modulation can be exactly carried out.

### (3) Third Embodiment

A third embodiment relates to a method of manufacturing a dual metal gate electrode based on the third basic configuration, and is an example in which work function modulation is carried out by precipitating a material with a low work function directly on a gate insulating layer.

In the third embodiment, a gate structure in which polysilicon is laminated on metal will be described.

A. Device Structure

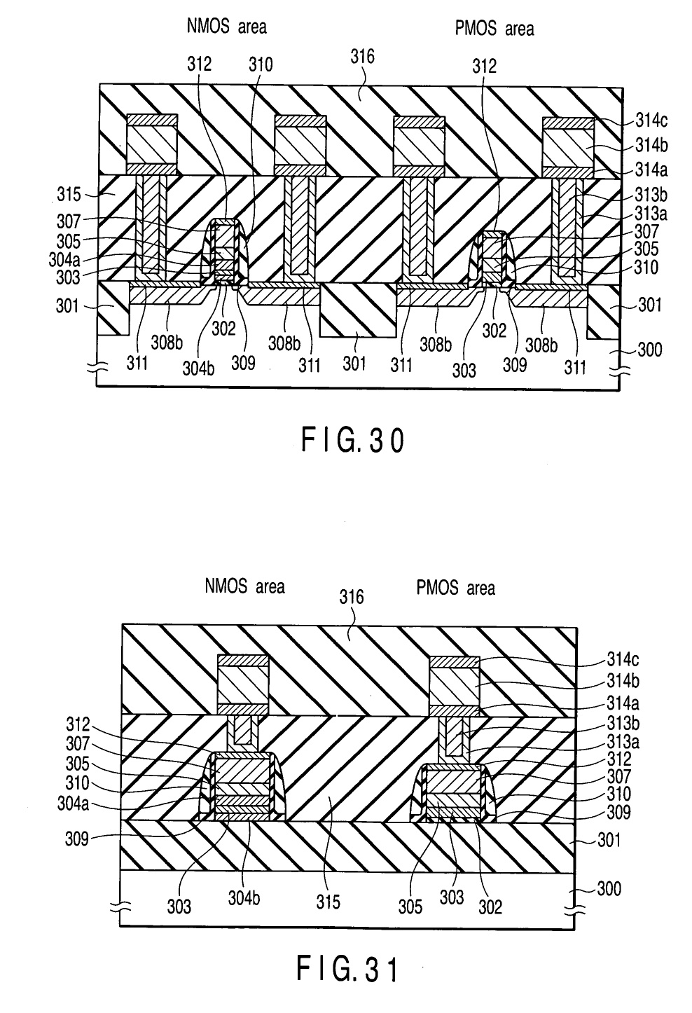

FIG. 29 is a plan view of a CMOS circuit which is formed by the method according to the third embodiment. FIG. 30 is a cross-sectional view taken along the line XXX-XXX of FIG. 29, and FIG. 31 is a cross-sectional view taken along the line XXXI-XXXI of FIG. 29.

An isolation layer 301 having an STI structure is arranged in a semiconductor substrate 300. As a consequence, a PMOS area in which a p-channel MOS transistor is formed and an NMOS area in which an n-channel MOS transistor is formed are formed.

The p-channel MOS transistor is configured by source/drain diffusion layers 308b, a gate insulating layer 302 on a channel between the source/drain diffusion layers 308b, and a gate electrode on the gate insulating layer 302.

The gate electrode is composed of a tungsten (W) layer 303 on the gate insulating layer 302, a titanium nitride (TiN) layer 305 on the tungsten layer 303, a polysilicon layer 307 on the titanium nitride layer 305, and a nickel silicide layer 312 on the polysilicon layer 307.

Silicon nitride layers 309 and silicon oxide layers 310 serving as sidewalls are arranged at the sidewall portions of the gate electrode.

Nickel silicide layers 311 are formed on the surface regions of the source/drain diffusion layers 308b.

Electrodes composed of titanium nitride layers 314a and 314c, and an aluminum layer 314b are connected to the nickel silicide layers 311 and 312 via titanium/titanium nitride 313a serving as barrier metals and tungsten 313b serving as contact plugs.

The n-channel MOS transistor is configured by source/drain diffusion layers 308b, a gate insulating layer 302 on a channel between the source/drain diffusion layers 308b, and a gate electrode on the gate insulating layer 302.

The gate electrode is composed of a gallium (Ga) precipitate layer 304b on the gate insulating layer 302, a tungsten layer 303 on the gallium precipitate layer 304b, a GaSb layer 304a on the tungsten layer 303, a titanium nitride layer 305 on the GaSb layer 304a, a polysilicon layer 307 on the titanium nitride layer 305, and a nickel silicide layer 312 on the polysilicon layer 307.

Here, the tungsten layer 303, the titanium nitride layer 305, the polysilicon layer 307, and the nickel silicide layer 312 are the same as the tungsten layer 303, the titanium nitride layer 305, the polysilicon layer 307, and the nickel silicide layer 312 which configure the gate electrode of the p-channel MOS transistor.

Silicon nitride layers 309 and silicon oxide layers 310 serving as sidewalls are arranged at the sidewall portions of the gate electrode.

Nickel silicide layers 311 are formed on the surface regions of the source/drain diffusion layers 308b.

Electrodes composed of titanium nitride layers 314a and 314c, and an aluminum layer 314b are connected to the nickel silicide layers 311 and 312 via titanium/titanium nitride 313a serving as barrier metals and tungsten 313b serving as contact plugs.

Both of the p-channel MOS transistor and the n-channel MOS transistor are covered with silicon oxide layers 315 and 316 serving as interlayer insulating layers.

B. Method of Manufacturing Semiconductor Device

A method of manufacturing a dual metal gate electrode by work function modulation according to the third embodiment will be described.

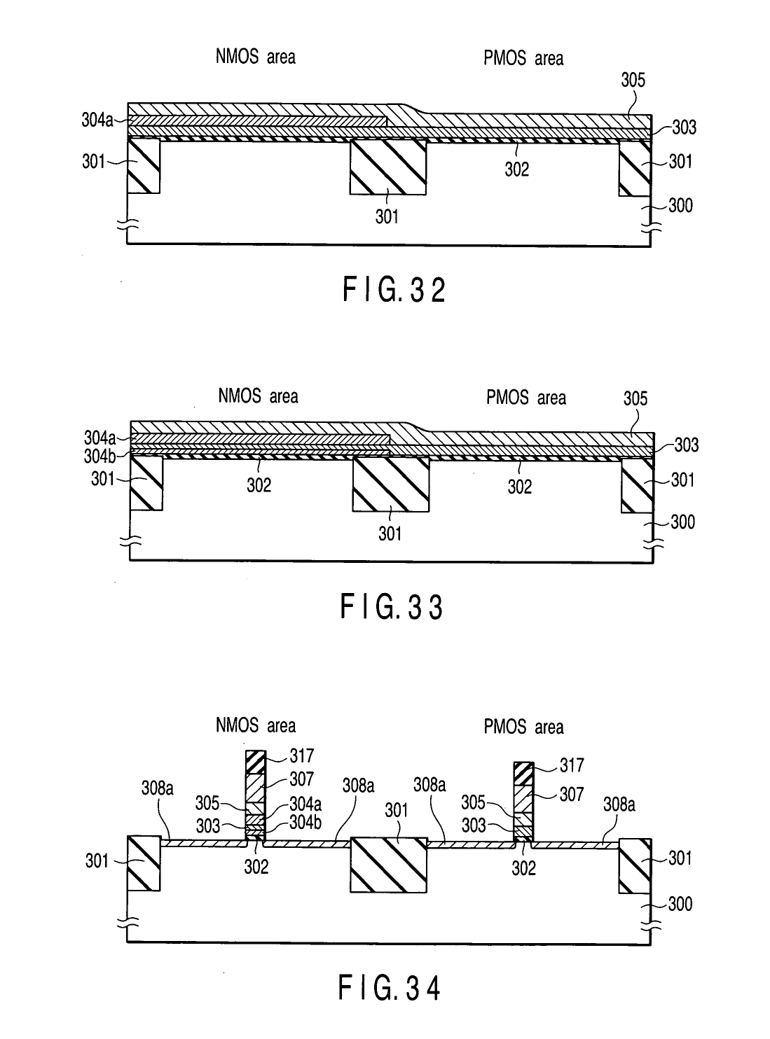

First, as shown in FIG. 32, an isolation layer 301 having an STI structure is formed in a semiconductor substrate 300, and a gate insulating layer 302 is formed by a thermal oxidation method on device regions separated by the isolation layer 301. Further, a tungsten layer 303 is formed so as to have a thickness of about 20 nm on the gate insulating layer 302 by, for example, a CVD method using an organic source.

Thereafter, a GaSb layer 304a is formed so as to have a thickness of about 20 nm on the tungsten layer 303 by, for example, sputtering. Further, the GaSb layer 304a in the PMOS area is selectively removed by, for example, PEP and RIE.

In addition, a titanium nitride layer 305 is formed so as to have a thickness of about 20 nm on the tungsten layer 303 and the GaSb layer 304a by, for example, a CVD method using an organic source. At this point in time, the NMOS area is made to be a laminated structure of W/GaSb/TiN in which the GaSb layer 304a is held between the tungsten layer 303 and the titanium nitride layer 305.

Next, as shown in FIG. 33, thermal treatment at about 500° C. for about thirty seconds is carried out in the nitrogen atmosphere, for example. As a result, Ga in the GaSb layer 304a diffuses via a grain boundary of the tungsten layer 303, and is precipitated at an interface between the gate insulating layer 302 and the tungsten layer 303 to become a gallium precipitate layer 304b.

Here, at the time of thermal treatment, the titanium nitride layer 305 functions as a cap layer which prevents the condensation of the GaSb layer 304a serving as a compound semiconductor.

Note that, because the GaSb layer 304a has a characteristic that condensation is relatively hard to bring about, the titanium nitride layer 305 can be omitted.

Next, as shown in FIG. 34, a polysilicon layers 307 are formed so as to have a thickness of about 90 nm on the titanium nitride layers 305 by, for example, a CVD method. Next, in the PMOS area, a p-type impurity (for example, B) is ion-implanted into the polysilicon layer 307, and in the NMOS area, an n-type impurity (for example, P) is ion-implanted into the polysilicon layer 307.

Thereafter, silicon nitride layers 317 are formed on the polysilicon layers 307 by, for example, a CVD method. Patterning is carried out onto the silicon nitride layers 317 by PEP and RIE, and moreover, the polysilicon layer 307, the titanium nitride layer 305, the GaSb layer 304a, the tungsten layer 303, the gallium precipitate layer 304b, and the gate insulating layer 302 are successively etched with the silicon nitride layers 317 being as masks by RIE.

As a result, a metal gate electrode of a p-channel. MOS transistor composed of a lamination layer of W/TiN/poly-Si, and a metal gate electrode of an n-channel MOS transistor composed of a lamination layer of Ga/W/GaSb/TiN/poly-Si is formed in the NMOS area.

Thereafter, extension diffusion layers 308a are formed, with the metal gate electrodes being as masks, by carrying out ion implantation of a p-type impurity (for example, B, BF₂, or the like) into the PMOS area in a self-alignment manner, and by carrying out ion implantation of an n-type impurity (for example, P, As, or the like) into the NMOS area in a self-alignment manner.

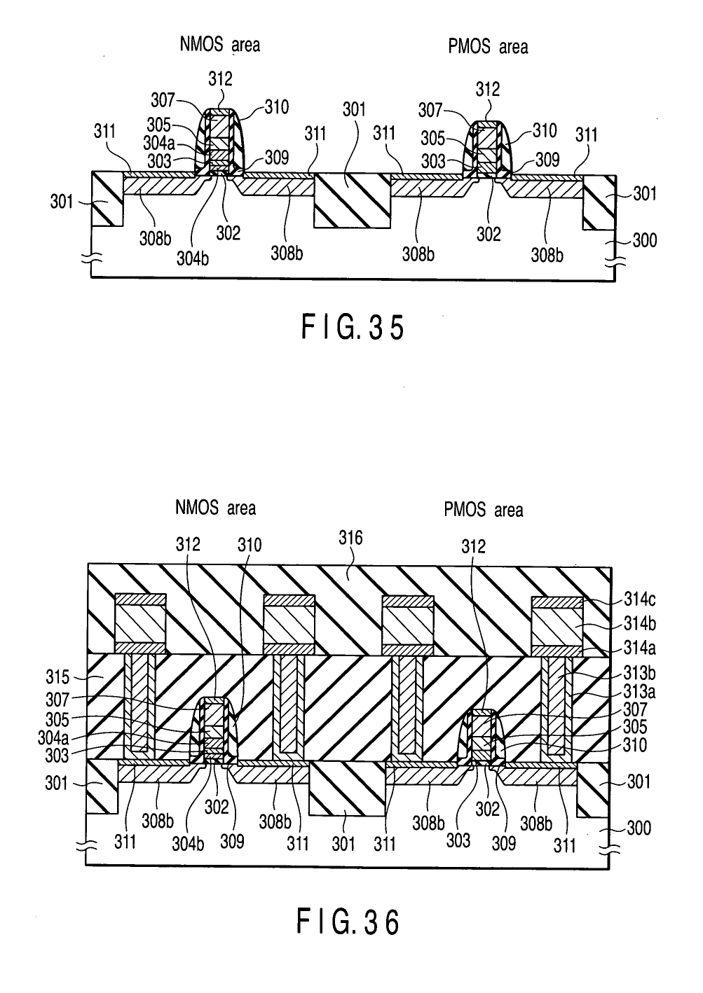

Next, as shown in FIG. 35, silicon nitride layers 309 and silicon oxide layers 310 are formed by, for example, a CVD method. Further, the silicon nitride layers 309 and the silicon oxide layers 310 are etched by RIE, and those are made to remain as sidewalls at the sidewall portions of the metal gate electrode.

Thereafter, source/drain layers 308b are formed, with the metal gate electrodes and the sidewalls being as masks, by carrying out ion implantation of a p-type impurity (for example, B, BF₂, or the like) into the PMOS area in a self-alignment manner, and by carrying out ion implantation of an n-type impurity (for example, P, As, or the like) into the NMOS area in a self-alignment manner.

Further, nickel (Ni) layers are formed so as to have a thickness of about 10 nm on the source/drain layers 308b and the polysilicon layers 307 by, for example, sputtering. Then, silicon (Si) in the source/drain layers 308b and the polysilicon layers 307, and nickel (Ni) in the nickel layers are made to react with each other by carrying out thermal treatment at about 350° C. for about thirty seconds.

Thereafter, unreacted nickel layers are removed by using, for example, a compound liquid of sulfuric acid and hydrogen peroxide, and nickel silicide layers 311 and 312 are formed by carrying out thermal treatment at about 500° C. for about thirty seconds.

Next, as shown in FIG. 36, a silicon oxide layer 315 covering the p-channel MOS transistor and the n-channel MOS transistor is formed by, for example, a CVD method. Further, the surface of the silicon oxide layer 315 is planarized by, for example, a chemical mechanical grinding (CMP) method.

After contact holes coming down to the source/drain diffusion layers 308b are formed at the silicon oxide layer 315, titanium/titanium nitride 313a serving as barrier metals and tungsten 313b serving as contact plugs are formed in the contact holes.

Electrodes composed of titanium nitride layers 314a and 314c, and an aluminum layer 314b are formed on the silicon oxide layer 315, and a silicon oxide layer 316 covering those electrodes is formed on the silicon oxide layer 315.

The gate electrode of the p-channel MOS transistor formed by such a method is composed of a lamination layer of W/TiN/poly-Si/Ni-silicide, and W whose work function is 4.9 eV is arranged directly on the gate insulating layer 302.

In addition, the gate electrode of the n-channel MOS transistor is composed of a laminated structure of Ga/W/GaSb/TiN/poly-Si/Ni-silicide. Here, a threshold value of the n-channel MOS transistor depends on a work function of Ga precipitated directly on the gate insulating layer 202, and the value becomes 4.2 eV, so that work function modulation can be appropriately carried out.

Note that, as the gate insulating layer 302, not only silicon oxide, but also an oxide, a nitride, or an oxynitride of Hf, Zr, Ti, Ta, Al, Sr, Y, La and the like, or an oxide, a nitride, or an oxynitride as a compound of those elements and silicon can be used. For example, a high dielectric constant material such as a zirconium oxide and a hafnium oxide is used as the gate insulating layer 302.

C. Summary

In accordance with the third embodiment, in the method of manufacturing a dual metal gate electrode, the condensation of metal is prevented, so that a material with a low work function is precipitated directly on the gate insulating layer, and work function modulation can be exactly carried out.

### (4) Fourth Embodiment

A fourth embodiment relates to a method of manufacturing a dual metal gate electrode based on the third basic configuration, and is an example in which work function modulation is carried out by alloying.

In the fourth embodiment, a gate structure in which polysilicon is laminated on metal will be described.

A. Device Structure

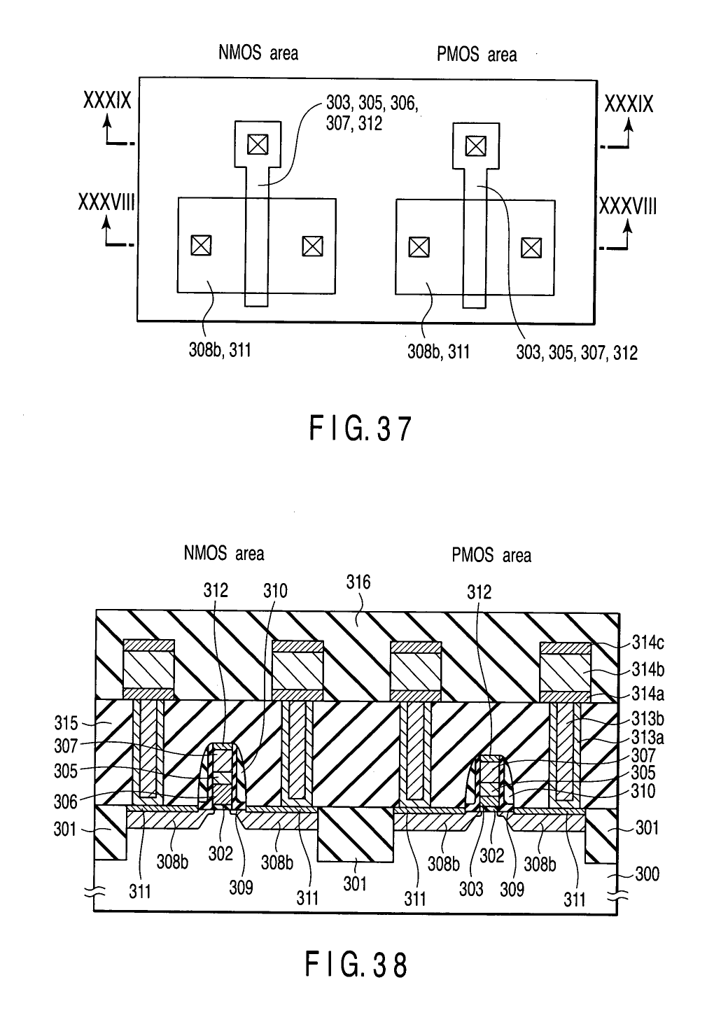

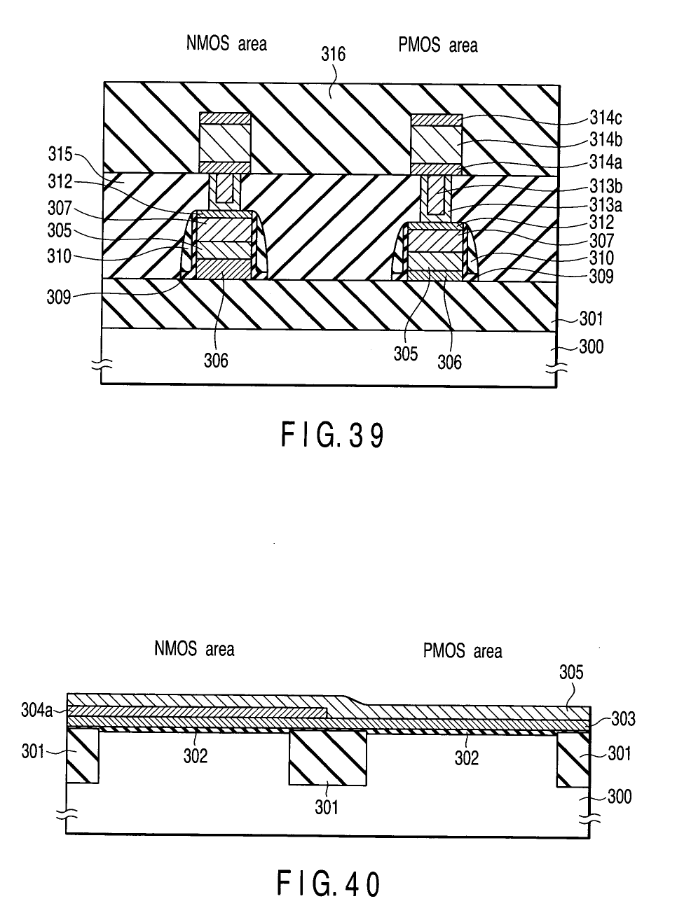

FIG. 37 is a plan view of a CMOS circuit which formed by the method according to the fourth embodiment. FIG. 38 is a cross-sectional view taken along the line XXXVIII-XXXVIII of FIG. 37, and FIG. 39 is a cross-sectional view taken along the line XXXIX-XXXIX of FIG. 37.

An isolation layer 301 having an STI structure is arranged in a semiconductor substrate 300. As a consequence, a PMOS area in which a p-channel MOS transistor is formed and an NMOS area in which an n-channel MOS transistor is formed are formed.

The p-channel MOS transistor is configured by source/drain diffusion layers 308b, a gate insulating layer 302 on a channel between the source/drain diffusion layers 308b, and a gate electrode on the gate insulating layer 302.

The gate electrode is configured by a tungsten (W) layer 303 on the gate insulating layer 302, a titanium nitride (TiN) layer 305 on the tungsten layer 303, a polysilicon layer 307 on the titanium nitride layer 305, and a nickel silicide layer 312 on the polysilicon layer 307.

Silicon nitride layers 309 and silicon oxide layers 310 serving as sidewalls are arranged at the sidewall portions of the gate electrode.

Nickel silicide layers 311 are formed on the surface regions of the source/drain diffusion layers 308b.

Electrodes composed of titanium nitride layers 314a and 314c, and an aluminum layer 314b are connected to the nickel silicide layers 311 and 312 via titanium/titanium nitride 313a serving as barrier metals and tungsten 313b serving as contact plugs.

The n-channel MOS transistor is configured by source/drain diffusion layers 308b, a gate insulating layer 302 on the channel between the source/drain diffusion layers 308b, and a gate electrode on the gate insulating layer 302.

The gate electrode is composed of a GaWSb layer 306 serving as an alloying layer on the gate insulating layer 302, a titanium nitride layer 305 on the GaWSb layer 306, a polysilicon layer 307 on the titanium nitride layer 305, and a nickel silicide layer 312 on the polysilicon layer 307.

Here, the titanium nitride layer 305, the polysilicon layer 307, and the nickel silicide layer 312 are the same as the titanium nitride layer 305, the polysilicon layer 307, and the nickel silicide layer 312 which configure the gate electrode of the p-channel MOS transistor.

Silicon nitride layers 309 and silicon oxide layers 310 serving as sidewalls are arranged at the sidewall portions of the gate electrode.

Nickel silicide layers 311 are formed on the surface regions of the source/drain diffusion layers 308b.

Electrodes composed of titanium nitride layers 314a and 314c, and an aluminum layer 314b are connected to the nickel silicide layers 311 and 312 via titanium/titanium nitride 313a serving as barrier metals and tungsten 313b serving as contact plugs.

Both of the p-channel MOS transistor and the n-channel MOS transistor are covered with silicon oxide layers 315 and 316 serving as interlayer insulating layers.

B. Method of Manufacturing Semiconductor Device

A method of manufacturing a dual metal gate electrode by work function modulation according to the fourth embodiment will be described.

First, as shown in FIG. 40, an isolation layer 301 having an STI structure is formed in a semiconductor substrate 300, and a gate insulating layer 302 is formed by a thermal oxidation method on device regions separated by the isolation layer 301. Further, a tungsten layer 303 is formed so as to have a thickness of about 20 nm on the gate insulating layer 302 by, for example, a CVD method using an organic source.

Thereafter, a GaSb layer 304a is formed so as to have a thickness of about 20 nm on the tungsten layer 303 by, for example, sputtering. Further, the GaSb layer 304a in the PMOS area is selectively removed by, for example, PEP and RIE.

In addition, a titanium nitride layer 305 is formed so as to have a thickness of about 20 nm on the tungsten layer 303 and the GaSb layer 304a by, for example, a CVD method using an organic source. At this point in time, the NMOS area is made to be a laminated structure of W/GaSb/TiN in which the GaSb layer 304a is held between the tungsten layer 303 and the titanium nitride layer 305.

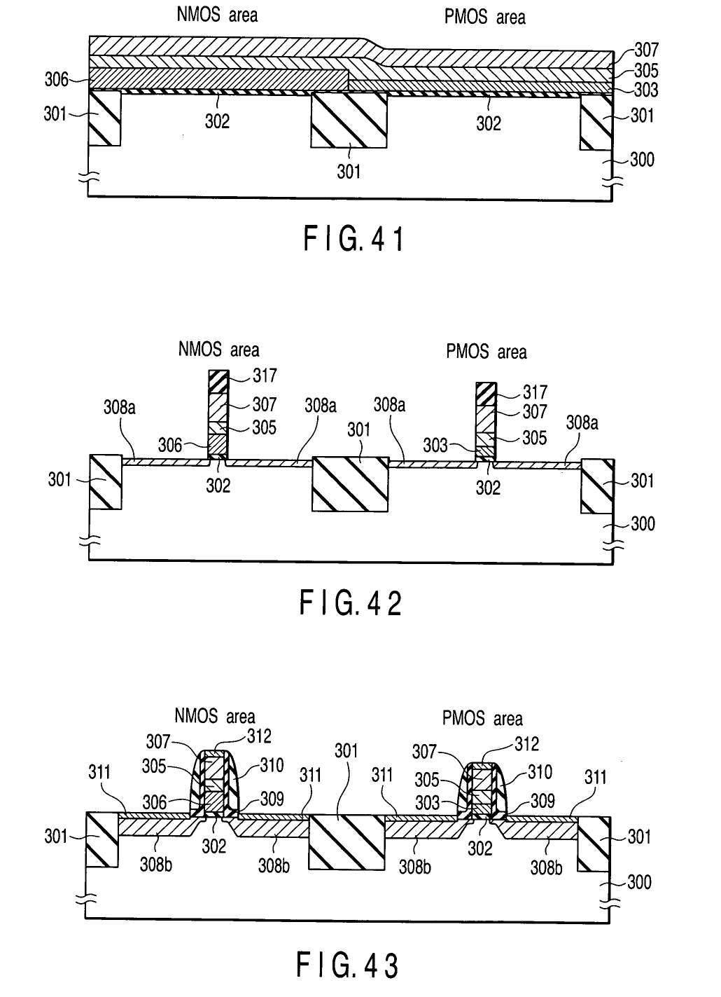

Next, as shown in FIG. 41, thermal treatment at about 400° C. for about one hour is carried out in the nitrogen atmosphere, for example. As a result, the tungsten layer 303 and the GaSb layer 304a chemically react with each other to become a GaWSb layer 306 serving as an alloy layer. Here, the thermal treatment is carried out under the conditions that the GaWSb layer 306 comes down to the gate insulating layer 302.

Note that, at the time of thermal treatment, the titanium nitride layer 305 functions as a cap layer preventing the GaSb layer 304a serving as a compound semiconductor from condensing. Further, because the GaSb layer 304a has a characteristic that condensation is relatively hard to bring about, the titanium nitride layer 305 can be omitted.

Next, as shown in FIG. 42, a polysilicon layer 307 is formed so as to have a thickness of about 90 nm on the titanium nitride layer 305 by, for example, a CVD method. Next, in the PMOS area, a p-type impurity (for example, B) is ion-implanted into the polysilicon layer 307, and in the NMOS area, an n-type impurity (for example, P) is ion-implanted into the polysilicon layer 307.

Thereafter, a silicon nitride layer 317 is formed on the polysilicon layer 307 by, for example, a CVD method. Patterning is carried out onto the silicon nitride layer 317 by PEP and RIE, and moreover, the polysilicon layer 307, the titanium nitride layer 305, the GaWSb layer 306, the tungsten layer 303, and the gate insulating layer 302 are successively etched with the silicon nitride layer 317 being as a mask by RIE.

As a result, a metal gate electrode of a p-channel MOS transistor composed of a lamination layer of W/TiN/poly-Si in the PMOS area, and a metal gate electrode of an n-channel MOS transistor composed of a lamination layer of GaWSb/TiN/poly-Si is formed in the NMOS area.

Thereafter, extension diffusion layers 308a are formed, with the metal gate electrodes being as masks, by carrying out ion implantation of a p-type impurity (for example, B, BF₂, or the like) into the PMOS area in a self-alignment manner, and by carrying out ion implantation of an n-type impurity (for example, P, As, or the like) into the NMOS area in a self-alignment manner.

Next, as shown in FIG. 43, silicon nitride layers 309 and silicon oxide layers 310 are formed by, for example, a CVD method. Further, the silicon nitride layers 309 and the silicon oxide layers 310 are etched by RIE, and those are made to remain as sidewalls at the sidewall portions of the metal gate electrode.

Thereafter, source/drain layers 308b are formed, with the metal gate electrodes and the sidewalls being as masks, by carrying out ion implantation of a p-type impurity (for example, B, BF₂, or the like) into the PMOS area in a self-alignment manner, and by carrying out ion implantation of an n-type impurity (for example, P, As, or the like) into the NMOS area in a self-alignment manner.

Further, nickel (Ni) layers are formed so as to have a thickness of about 10 nm on the source/drain layers 308b and the polysilicon layers 307 by, for example, sputtering. Then, silicon (Si) in the source/drain layers 308b and the polysilicon layers 307, and nickel (Ni) in the nickel layers are made to react with each other by carrying out thermal treatment at about 350° C. for about thirty seconds.

Thereafter, unreacted nickel layers are removed by using, for example, a compound liquid of sulfuric acid and hydrogen peroxide, and nickel silicide layers 311 and 312 are formed by carrying out thermal treatment at about 500° C. for about thirty seconds.

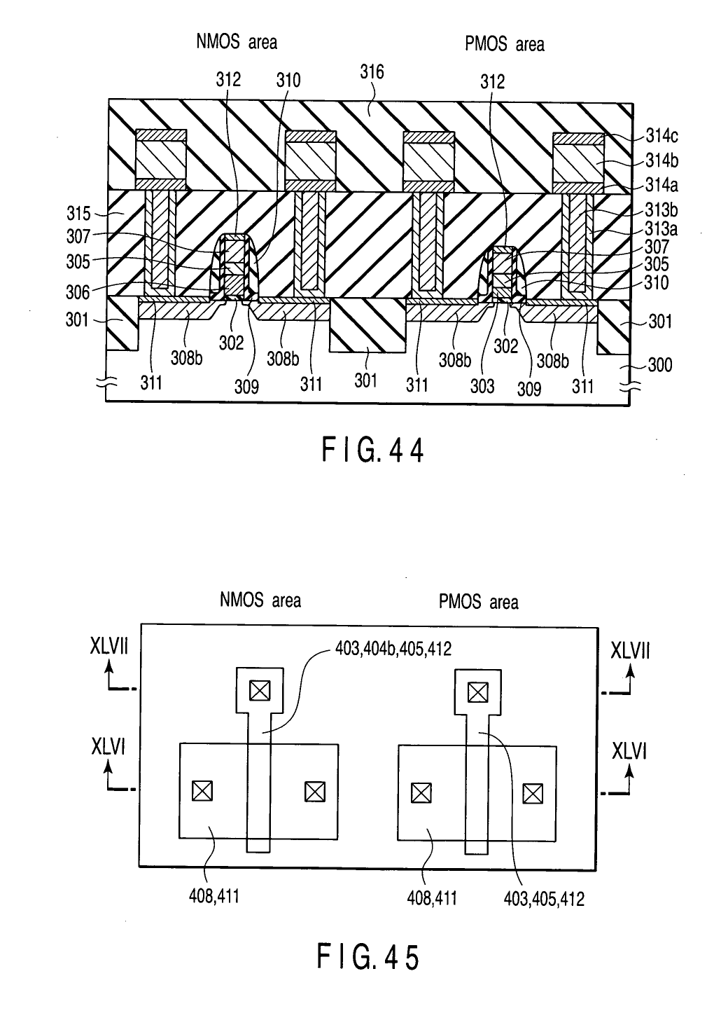

Next, as shown in FIG. 44, a silicon oxide layer 315 covering the p-channel MOS transistor and the n-channel MOS transistor is formed by, for example, a CVD method. Further, the surface of the silicon oxide layer 315 is planarized by, for example, a CMP method.

After contact holes coming down to the source/drain diffusion layers 308b are formed at the silicon oxide layer 315, titanium/titanium nitride 313a serving as barrier metals and tungsten 313b serving as contact plugs are formed in the contact holes.

Electrodes composed of titanium nitride layers 314a and 314c, and an aluminum layer 314b are formed on the silicon oxide layer 315, and a silicon oxide layer 316 covering those electrodes is formed on the silicon oxide layer 315.

The gate electrode of the p-channel MOS transistor formed by such a method is composed of a lamination layer of W/TiN/poly-Si/Ni-silicide, and W whose work function is 4.9 eV is arranged directly on the gate insulating layer 302.

In addition, the gate electrode of the n-channel MOS transistor is composed of a laminated structure of GaWSb/TiN/poly-Si/Ni-silicide. Here, a threshold value of the n-channel MOS transistor depends on a work function of GaWSb directly on the gate insulating layer 202, and the value becomes 4.1 eV, so that work function modulation can be appropriately carried out.

Note that, as the gate insulating layer 302, not only silicon oxide, but also an oxide, a nitride, or an oxynitride of Hf, Zr, Ti, Ta, Al, Sr, Y, La and the like, or an oxide, a nitride, or an oxynitride as a compound of those elements and silicon can be used in the same way as in the third embodiment. For example, a high dielectric constant material such as a zirconium oxide and a hafnium oxide is used as the gate insulating layer 302.

C. Summary

In accordance with the fourth embodiment, in the method of manufacturing a dual metal gate electrode, the condensation of metal is prevented, so that an alloy layer with a low work function is formed directly on the gate insulating layer, and work function modulation can be exactly carried out.

### (5) Fifth Embodiment

A fifth embodiment relates to an application example of the first to third basic configurations, and is an example in which elements contributing to work function modulation are injected into a gate electrode by ion implantation, and the elements are precipitated directly on the gate insulating layer by thermal treatment.

A. Device Structure

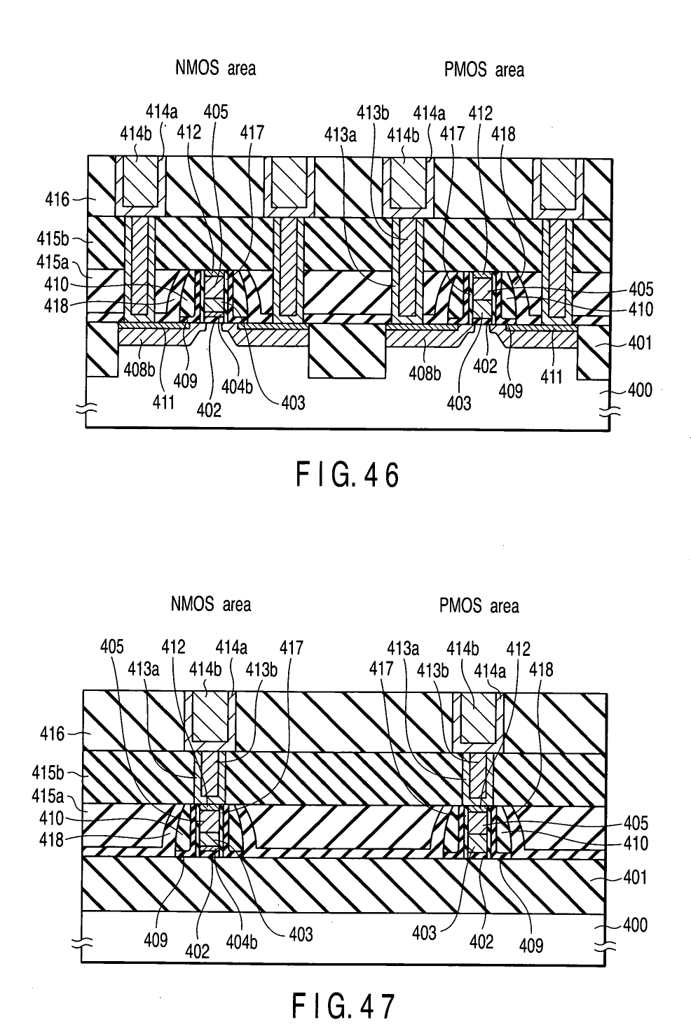

FIG. 45 is a plan view of a CMOS circuit which is formed by the method according to the fifth embodiment. FIG. 46 is a cross-sectional view taken along the line XLVI-XLVI of FIG. 45, and FIG. 47 is a cross-sectional view taken along the line XLVII-XLVII of FIG. 45.

An isolation layer 401 having an STI structure is arranged in a semiconductor substrate 400. As a consequence, a PMOS area in which a p-channel MOS transistor is formed and an NMOS area in which an n-channel MOS transistor is formed are formed.

The p-channel MOS transistor is configured by source/drain diffusion layers 408b, a gate insulating layer 402 on a channel between the source/drain diffusion layers 408b, and a gate electrode on the gate insulating layer 402.

The gate electrode is configured by a tungsten nitride (WN) layer 403 on the gate insulating layer 402, a polysilicon layer 405 on the tungsten nitride layer 403, and a nickel silicide layer 412 on the polysilicon layer 405. The polysilicon layer 405 is a conductive material including a p-type impurity (for example, B, BF₂, or the like).

Silicon nitride layers 417, silicon oxide layers 409, and silicon nitride layers 410 serving as sidewalls are arranged at the sidewall portions of the gate electrode. Moreover, silicon nitride layers 418 are arranged so as to cover the silicon nitride layers 410.

Nickel silicide layers 411 are formed on the surface regions of the source/drain diffusion layers 408b.

Electrodes composed of a tantalum nitride (TaN) layer 414a and a copper (Cu) layer 414b are connected to nickel silicide layers 411 and 412 via titanium/titanium nitride 413a serving as barrier metals and tungsten 413b serving as contact plugs.

The n-channel MOS transistor is configured by source/drain diffusion layers 408b, a gate insulating layer 402 on a channel between the source/drain diffusion layers 408b, and a gate electrode on the gate insulating layer 402.

The gate electrode is configured by an indium (In) precipitate layer 404b on the gate insulating layer 402, a tungsten nitride (WN) layer 403 on the indium precipitate layer 404b, a polysilicon layer 405 on the tungsten nitride layer 403, and a nickel silicide layer 412 on the polysilicon layer 405. The polysilicon layer 405 is a conductive material including an n-type impurity (for example, P, As, or the like).

Here, the tungsten nitride layer 403, the polysilicon layer 405, and the nickel silicide layer 412 are the same as the tungsten nitride layer 403, the polysilicon layer 405, and the nickel silicide layer 412 which configure the gate electrode of the p-channel MOS transistor.

Silicon nitride layers 417, silicon oxide layers 409, and silicon nitride layers 410 serving as sidewalls are arranged at the sidewall portions of the gate electrode. Moreover, silicon nitride layers 418 are arranged so as to cover the silicon nitride layers 410.

Nickel silicide layers 411 are formed on the surface regions of the source/drain diffusion layers 408b.

Electrodes composed of a tantalum nitride (TaN) layer 414a and a copper (Cu) layer 414b are connected to nickel silicide layers 411 and 412 via titanium/titanium nitride 413a serving as barrier metals and tungsten 413b serving as contact plugs.

Both of the p-channel MOS transistor and the n-channel MOS transistor are covered with silicon oxide layers 415a, 415b, and 416 serving as interlayer insulating layers.

B. Method of Manufacturing Semiconductor Device

A method of manufacturing a dual metal gate electrode by work function modulation according to the fifth embodiment will be described.

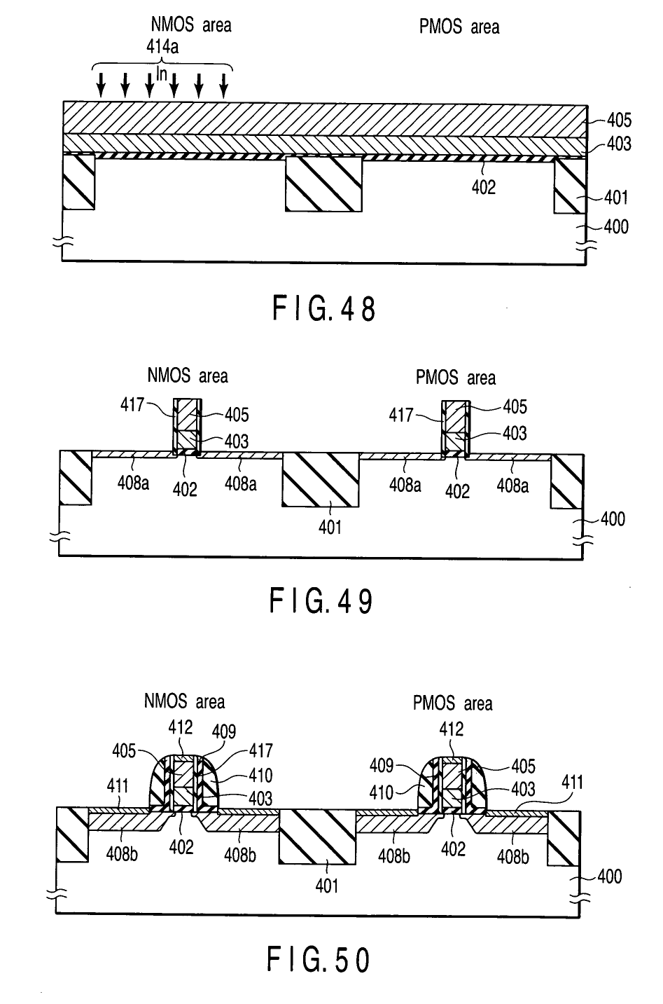

First, as shown in FIG. 48, an isolation layer 401 having an STI structure is formed in a semiconductor substrate 400, and a gate insulating layer 402 is formed by a thermal oxidation method on device regions separated by the isolation layer 401.

Then, a tungsten nitride layer 403 whose work function is 4.9 eV is formed so as to have a thickness of about 20 nm on the gate insulating layer 402 by, for example, a CVD method using an organic source. Subsequently, a polysilicon layer 405 is formed so as to have a thickness of about 100 nm on the tungsten nitride layer 403 by, for example, a CVD method.

Thereafter, indium (In) 414a is ion-implanted into the polysilicon layer 405 in the NMOS area under the conditions that an accelerating energy is about 40 keV, and a dose amount is about 5×10¹⁵ cm⁻².

Next, as shown in FIG. 49, etching is successively carried out onto the polysilicon layer 405, the tungsten nitride layer 403, and the gate insulating layer 402 by PEP and RIE. in the PMOS area, a gate electrode of a p-channel MOS transistor whose gate width (channel length) is, for example, 30 nm is formed, and in the NMOS area, a gate electrode of a p-channel MOS transistor whose gate width is, for example, 20 nm is formed.

Then, silicon nitride layers 417 covering the p-channel MOS transistor and the n-channel MOS transistor are formed so as to have a thickness of about 8 nm, and etch back is carried out thereon, which makes the silicon nitride layers 417 remain at the sidewall portions of the gate electrode.

Further, with the gate electrodes being as masks, a p-type impurity (for example, B, BF₂, or the like) is ion-implanted into the PMOS area in a self-alignment manner, and an n-type impurity (for example, P, As, or the like) is ion-implanted into the NMOS area in a self-alignment manner, so that extension diffusion layers 408a are formed by carrying out thermal treatment at about 800° C. for about five seconds.

Next, as shown in FIG. 50, silicon oxide layers 409 and silicon nitride layers 410 are formed by, for example, a CVD method, and etch back is carried out thereon, which makes the silicon oxide layers 409 and the silicon nitride layers 410 remain as sidewalls at the sidewall portions of the gate electrodes.

Further, with the gate electrodes and the side walls being as masks, a p-type impurity (for example, B, BF₂, or the like) is ion-implanted into the PMOS area in a self-alignment manner, and an n-type impurity (for example, P, As, or the like) is ion-implanted into the NMOS area in a self-alignment manner, so that source/drain layers 408b are formed by carrying out thermal treatment at about 1000° C. for about one second.

Thereafter, nickel (Ni) layers are formed so as to have a thickness of about 10 nm on the source/drain layers 408b and the polysilicon layers 405 by, for example, sputtering. Then, silicon (Si) in the source/drain layers 408b and the polysilicon layers 405 and nickel (Ni) in the nickel layers are made to react with each other by carrying out thermal treatment at about 350° C. for about thirty seconds.

Thereafter, unreacted nickel layers are removed by using, for example, a compound liquid of sulfuric acid and hydrogen peroxide, and nickel silicide layers 411 and 412 are formed by carrying out thermal treatment at about 500° C. for about thirty seconds again.

Next, as shown in FIG. 51, silicon nitride layers 418 covering the p-channel MOS transistor and the n-channel MOS transistor are formed so as to have a thickness of about 30 nm by, for example, a CVD method. Subsequently, a silicon oxide layer 415a serving as an interlayer insulating layer is formed so as to have a thickness of about 250 nm on the silicon nitride layers 418 by, for example, a CVD method.

Then, the silicon nitride layers 418 and the silicon oxide layer 415a are planarized by grinding until the top surfaces of the gate electrodes are exposed. At that time, there are cases in which the nickel silicide layers 412 which are the uppermost layers of the gate electrodes are grinded, and some or the entire thereof are removed.

In such a case, a nickel (Ni) layer 419 is formed again so as to have a thickness of about 10 nm on the planarized silicon nitride layers 418 and silicon oxide layers 415a by, for example, sputtering. In addition, silicon (Si) in the polysilicon layers 405 and nickel (Ni) in the nickel layers are made to react with each other by carrying out thermal treatment at about 350° C. for about thirty seconds.

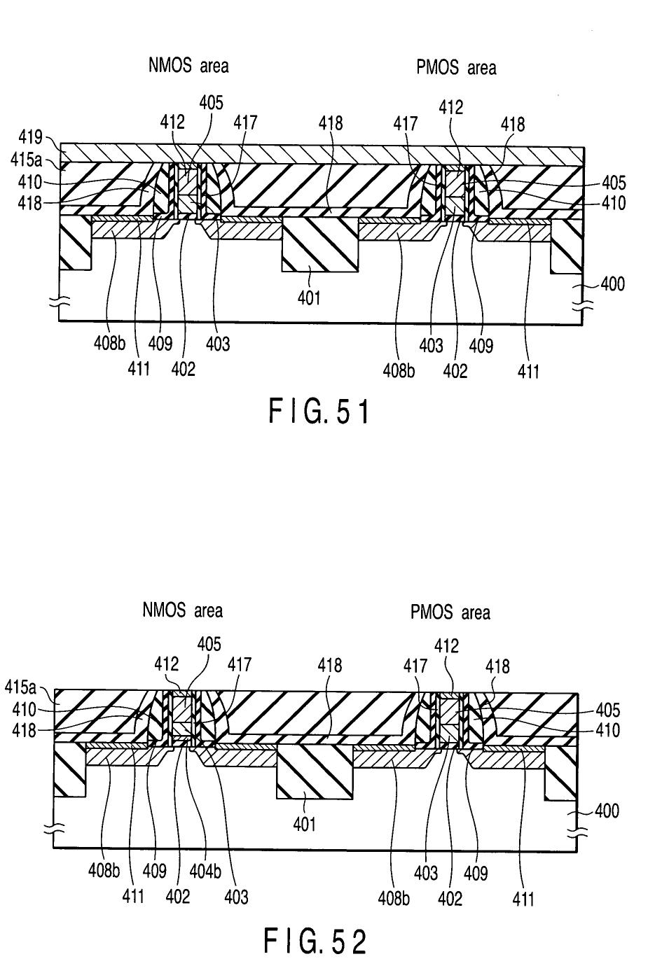

Further, as shown in FIG. 52, unreacted nickel layers are removed by using, for example, a compound liquid of sulfuric acid and hydrogen peroxide, and then, the nickel silicide layers 412 are formed again by carrying out thermal treatment at about 500° C. for about thirty seconds.

By the way, from the time ion implantation of indium has been carried out into the polysilicon layer 405 up to the present stage, as described above, a plurality of thermal treatment steps are executed. Due to those thermal treatments, indium is precipitated at an interface between the gate insulating layer 402 and the tungsten nitride layer 403 via a grain boundary of the tungsten nitride layer 403 to become an indium precipitate layer 404b.

The work function of the gate electrode of the n-channel MOS transistor becomes 4.1 eV due to the indium precipitate layer 404b.

Note that the nickel layer 419 of FIG. 51 functions so as to prevent the indium in the polysilicon layers 405 from diffusing outward at the time of thermal treatment.

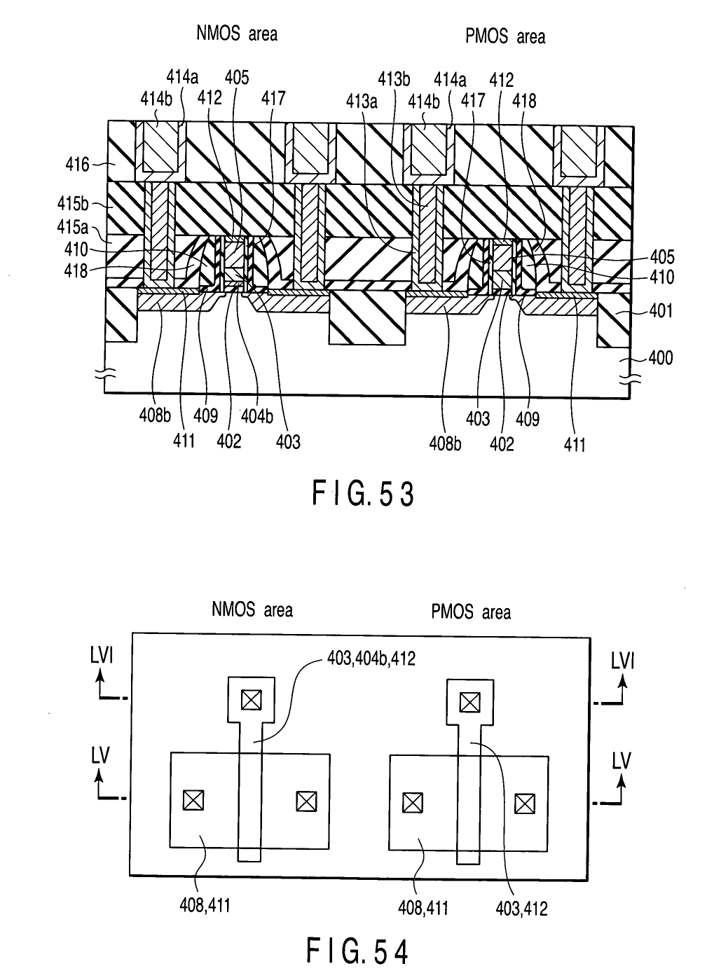

Next, as shown in FIG. 53, a silicon oxide layer 415b is formed on the silicon oxide layer 415a by, for example, a CVD method. Further, the surface of the silicon oxide layer 415b is planarized by, for example, a CMP method.

After contact holes coming down to the source/drain diffusion layers 408b are formed at the silicon oxide layers 415a and 415b and the silicon nitride layers 418, titanium/titanium nitride 413a serving as barrier metals and tungsten 413b serving as contact plugs are formed in the contact holes.

Further, a silicon oxide layer 416 is formed on the silicon oxide layer 415b by, for example, a CVD method. Further, the surface of the silicon oxide layer 416 is planarized by, for example, a CMP method.

After wiring grooves coming down to the tungsten 413b serving as contact plugs are formed at the silicon oxide layer 416, electrodes composed of tantalum nitride layers 414a and copper layers 414b are embedded into the wiring grooves.

A work function of the gate electrode of the p-channel MOS transistor formed by such a method is determined by WN, and the value becomes 4.9 eV. In contrast thereto, a work function of the gate electrode of the n-channel MOS transistor is determined by In, and the value becomes 3.9 eV.

Note that, with respect to the gate electrode of the p-channel MOS transistor, the material can be selected from among metals such as W, Pd, Pt, Ni, Co, Rb, Ir, Nb, Mo, Ta, Sb, Bi, Er and Ti, an alloy including at least one of those metals, and a nitride, a carbide, or a silicon nitride of those metals.

A material for use in work function modulation, here, elements injected into the polysilicon layers 405 by ion implantation can be selected from among In, Ga, Tl, Sb, Bi and the like.

As the gate electrode layer 202, not only silicon oxide, but also an oxide, a nitride, or an oxynitride of Hf, Zr, Ti, Ta, Al, Sr, Y, La and the like, or an oxide, a nitride, or an oxynitride as a compound of those elements and silicon can be used.

For example, a high dielectric constant material such as a zirconium oxide and a hafnium oxide is used as the gate insulating layer 202.

In the fifth embodiment, the elements injected into the polysilicon layers 405 are precipitated directly on the gate insulating layers 402. However, as in the second and fourth embodiments described above, an alloy layer is formed by using the elements injected into the polysilicon layers 405, and work function modulation may be carried out by the alloy layer.

In addition, the elements for use in work function modulation are injected into the polysilicon layers by ion implantation. However, those may be injected by another method. Although the layers into which the elements for use in work function modulation are injected are not limited to the polysilicon layers, and are preferably semiconductor layers.

C. Summary

In accordance with the fifth embodiment, in the method of manufacturing a dual metal gate electrode, a material with a low work function is precipitated directly on the gate insulating layer due to ion implantation and thermal treatment, so that work function modulation can be exactly carried out.

### (6) Sixth Embodiment

A sixth embodiment relates to an application example of the first to third basic configurations, and is an example in which elements contributing to work function modulation are injected into a gate electrode by ion implantation, and the elements are precipitated directly on the gate insulating layer by thermal treatment.

A. Device Structure

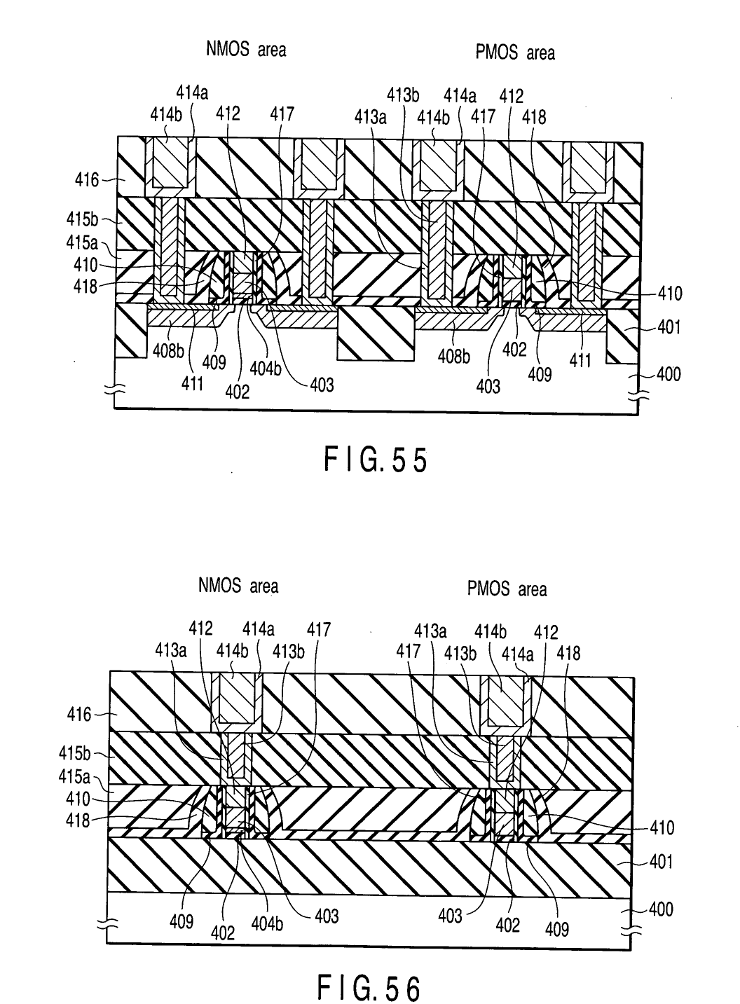

FIG. 54 is a plan view of a CMOS circuit which is formed by the method according to the sixth embodiment. FIG. 55 is a cross-sectional view taken along the line LV-LV of FIG. 54, and FIG. 56 is a cross-sectional view taken along the line LVI-LVI of FIG. 54.

An isolation layer 401 having an STI structure is arranged in a semiconductor substrate 400. As a consequence, a PMOS area in which a p-channel MOS transistor is formed and an NMOS area in which an n-channel MOS transistor is formed are formed.

The p-channel MOS transistor is configured by source/drain diffusion layers 408b, a gate insulating layer 402 on a channel between the source/drain diffusion layers 408b, and a gate electrode on the gate insulating layer 402.

The gate electrode is configured by a tungsten nitride (WN) layer 403 on the gate insulating layer 402 and a nickel silicide layer 412 on the tungsten nitride layer 403.

Silicon nitride layers 417, silicon oxide layers 409, and silicon nitride layers 410 serving as sidewalls are arranged at the sidewall portions of the gate electrode. Moreover, silicon nitride layers 418 are arranged so as to cover the silicon nitride layers 410.

Nickel silicide layers 411 are formed on the surface regions of the source/drain diffusion layers 408b.

Electrodes composed of a tantalum nitride (TaN) layer 414a and a copper (Cu) layer 414b are connected to nickel silicide layers 411 and 412 via titanium/titanium nitride 413a serving as barrier metals and tungsten 413b serving as contact plugs.

The n-channel MOS transistor is configured by source/drain diffusion layers 408b, a gate insulating layer 402 on a channel between the source/drain diffusion layers 408b, and a gate electrode on the gate insulating layer 402.

The gate electrode is configured by an indium (In) precipitate layer 404b on the gate insulating layer 402, a tungsten nitride (WN) layer 403 on the indium precipitate layer 404b, and a nickel silicide layer 412 on the tungsten nitride layer 403.

Here, the tungsten nitride layer 403 and the nickel silicide layer 412 are the same as the tungsten nitride layer 403 and the nickel silicide layer 412 which configure the gate electrode of the p-channel MOS transistor.

Silicon nitride layers 417, silicon oxide layers 409, and silicon nitride layers 410 serving as sidewalls are arranged at the sidewall portions of the gate electrode. Moreover, silicon nitride layers 418 are arranged so as to cover the silicon nitride layers 410.

Nickel silicide layers 411 are formed on the surface regions of the source/drain diffusion layers 408b.

Electrodes composed of a tantalum nitride (TaN) layer 414a and a copper (Cu) layer 414b are connected to nickel silicide layers 411 and 412 via titanium/titanium nitride 413a serving as barrier metals and tungsten 413b serving as contact plugs.

Both of the p-channel MOS transistor and the n-channel MOS transistor are covered with silicon oxide layers 415a, 415b, and 416 serving as interlayer insulating layers.

B. Method of Manufacturing Semiconductor Device

A method of manufacturing a dual metal gate electrode by work function modulation according to the sixth embodiment will be described.

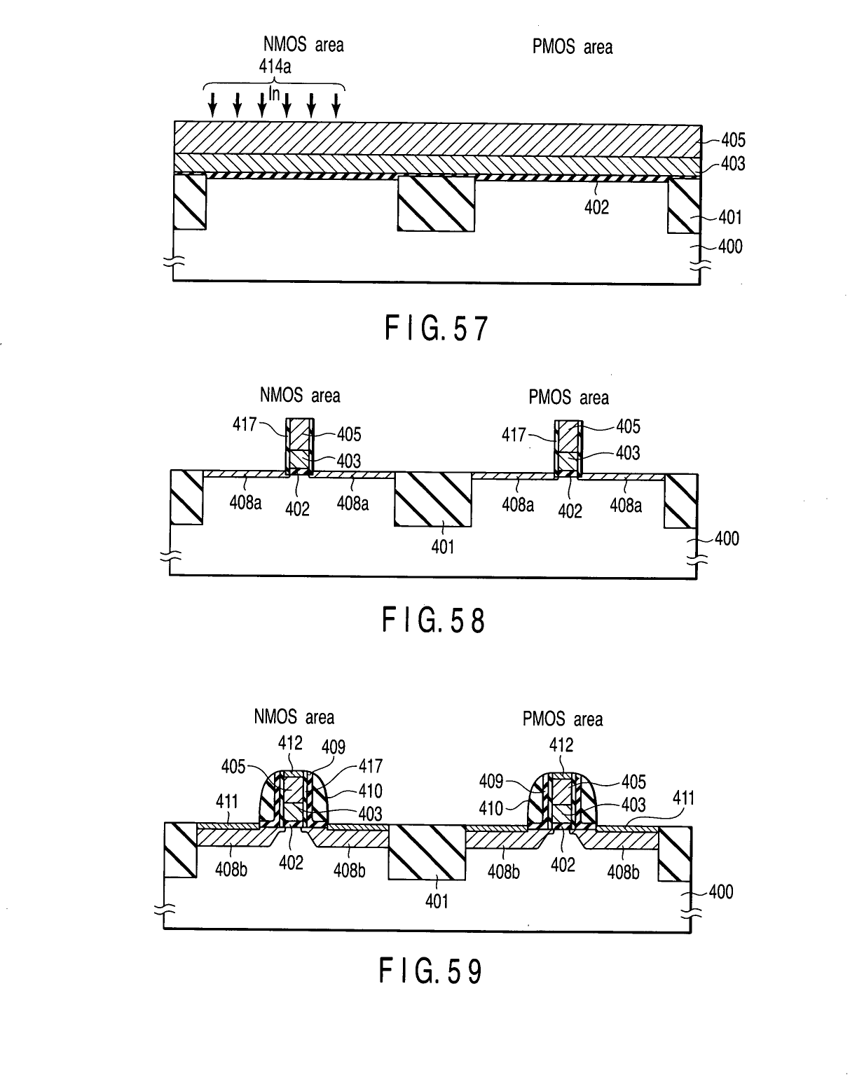

First, as shown in FIG. 57, an isolation layer 401 having an STI structure is formed in a semiconductor substrate 400, and a gate insulating layer 402 is formed by a thermal oxidation method on device regions separated by the isolation layer 401.

Then, a tungsten nitride layer 403 whose work function is 4.9 eV is formed so as to have a thickness of about 20 nm on the gate insulating layer 402 by, for example, a CVD method using an organic source. Subsequently, a polysilicon layer 405 is formed so as to have a thickness of about 100 nm on the tungsten nitride layer 403 by, for example, a CVD method.

Thereafter, indium (In) 414a is ion-implanted into the polysilicon layer 405 in the NMOS area under the conditions that an accelerating energy is about 40 keV, and a dose amount is about 5×10¹⁵ cm⁻².

Next, as shown in FIG. 58, etching is successively carried out onto the polysilicon layer 405, the tungsten nitride layer 403, and the gate insulating layer 402 by PEP and RIE. in the PMOS area, a gate electrode of a p-channel MOS transistor whose gate width (channel length) is, for example, 30 nm is formed, and in the NMOS area, a gate electrode of a p-channel MOS transistor whose gate width is, for example, 20 nm is formed.

Then, silicon nitride layers 417 covering the p-channel MOS transistor and the n-channel MOS transistor are formed so as to have a thickness of about 8 nm, and etch back is carried out thereon, which makes the silicon nitride layers 417 remain at the sidewall portions of the gate electrode.

Further, with the gate electrodes being as masks, a p-type impurity (for example, B, BF₂, or the like) is ion-implanted into the PMOS area in a self-alignment manner, and an n-type impurity (for example, P, As, or the like) is ion-implanted into the NMOS area in a self-alignment manner, so that extension diffusion layers 408a are formed by carrying out thermal treatment at about 800° C. for about five seconds.

Next, as shown in FIG. 59, silicon oxide layers 409 and silicon nitride layers 410 are formed by, for example, a CVD method, and etch back is carried out thereon, which makes the silicon oxide layers 409 and the silicon nitride layers 410 remain as sidewalls at the sidewall portions of the gate electrodes.

Further, with the gate electrodes and the side walls being as masks, a p-type impurity (for example, B, BF₂, or the like) is ion-implanted into the PMOS area in a self-alignment manner, and an n-type impurity (for example, P, As, or the like) is ion-implanted into the NMOS area in a self-alignment manner, so that source/drain layers 408b are formed by carrying out thermal treatment at about 1000° C. for about one second.

Thereafter, nickel (Ni) layers are formed so as to have a thickness of about 10 nm on the source/drain layers 408b and the polysilicon layers 405 (see FIG. 58) by, for example, sputtering. Then, silicon (Si) in the source/drain layers 408b and the polysilicon layers 405 (see FIG. 58) and nickel (Ni) in the nickel layers are made to react with each other by carrying out thermal treatment at about 350° C. for about thirty seconds.

Thereafter, unreacted nickel layers are removed by using, for example, a compound liquid of sulfuric acid and hydrogen peroxide, and nickel silicide layers 411 and 412 are formed by carrying out thermal treatment at about 500° C. for about thirty seconds again.

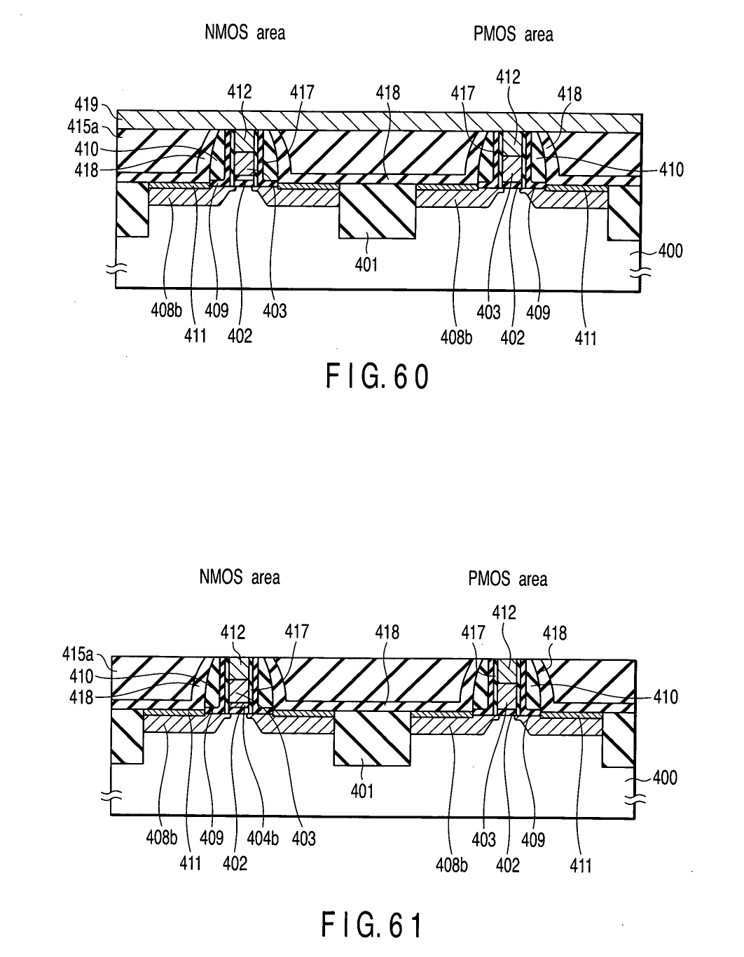

Next, as shown in FIG. 60, silicon nitride layers 418 covering the p-channel MOS transistor and the n-channel MOS transistor are formed so as to have a thickness of about 30 nm by, for example, a CVD method. Subsequently, a silicon oxide layer 415a serving as an interlayer insulating layer is formed so as to have a thickness of about 250 nm on the silicon nitride layers 418 by, for example, a CVD method.

Then, the silicon nitride layers 418 and the silicon oxide layer 415a are planarized by grinding until the top surfaces of the gate electrodes are exposed. At that time, there are cases in which the nickel silicide layers 412 which are the uppermost layers of the gate electrodes are grinded, and some or the entire thereof are removed.

In such a case, a nickel (Ni) layer 419 is formed again so as to have a thickness of about 40 nm on the planarized silicon nitride layers 418 and silicon oxide layers 415a by, for example, sputtering. In addition, a thermal treatment at about 350° C. for about thirty seconds is executed.

Further, as shown in FIG. 61, unreacted nickel layers are removed by using, for example, a compound liquid of sulfuric acid and hydrogen peroxide, and then, the nickel silicide layers 412 are formed again by carrying out thermal treatment at about 500° C. for about thirty seconds.

By the way, from the time ion implantation of indium has been carried out into the polysilicon layer 405 (see FIG. 58) up to the present stage, as described above, a plurality of thermal treatment steps are executed.

Due to those thermal treatments, by a snowplow effect occurred during silicide reaction, indium is segregated at the interface between silicide and gate insulator. That is, indium is precipitated at an interface between the gate insulating layer 402 and the tungsten nitride layer 403 via a grain boundary of the tungsten nitride layer 403 to become an indium precipitate layer 404b.

The work function of the gate electrode of the n-channel MOS transistor becomes 4.1 eV due to the indium precipitate layer 404b.

Note that the nickel layer 419 of FIG. 60 functions so as to prevent the indium in the polysilicon layers 405 (see FIG. 58) from diffusing outward at the time of thermal treatment.

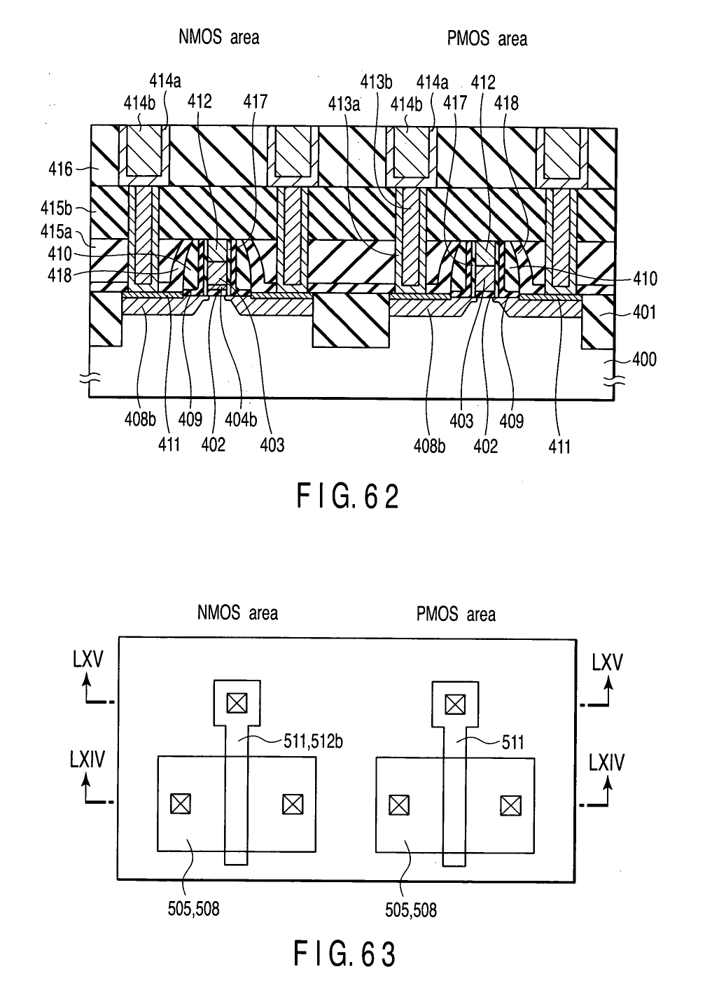

Next, as shown in FIG. 62, a silicon oxide layer 415b is formed on the silicon oxide layer 415a by, for example, a CVD method. Further, the surface of the silicon oxide layer 415b is planarized by, for example, a CMP method.

After contact holes coming down to the source/drain diffusion layers 408b are formed at the silicon oxide layers 415a and 415b and the silicon nitride layers 418, titanium/titanium nitride 413a serving as barrier metals and tungsten 413b serving as contact plugs are formed in the contact holes.

Further, a silicon oxide layer 416 is formed on the silicon oxide layer 415b by, for example, a CVD method. Further, the surface of the silicon oxide layer 416 is planarized by, for example, a CMP method.

After wiring grooves coming down to the tungsten 413b serving as contact plugs are formed at the silicon oxide layer 416, electrodes composed of tantalum nitride layers 414a and copper layers 414b are embedded into the wiring grooves.

A work function of the gate electrode of the p-channel MOS transistor formed by such a method is determined by WN, and the value becomes 4.9 eV. In contrast thereto, a work function of the gate electrode of the n-channel MOS transistor is determined by In, and the value becomes 3.9 eV.

Note that, with respect to the gate electrode of the p-channel MOS transistor, the material can be selected from among metals such as W, Pd, Pt, Ni, Co, Rb, Ir, Nb, Mo, Ta, Sb, Bi, Er and Ti, an alloy including at least one of those metals, and a nitride, a carbide, or a silicon nitride of those metals.

A material for use in work function modulation, here, elements injected into the polysilicon layers 405 by ion implantation can be selected from among In, Ga, Tl, Sb, Bi and the like.

As the gate electrode layer 202, not only silicon oxide, but also an oxide, a nitride, or an oxynitride of Hf, Zr, Ti, Ta, Al, Sr, Y, La and the like, or an oxide, a nitride, or an oxynitride as a compound of those elements and silicon can be used.

For example, a high dielectric constant material such as a zirconium oxide and a hafnium oxide is used as the gate insulating layer 202.

In the sixth embodiment, the elements injected into the polysilicon layers 405 are precipitated directly on the gate insulating layers 402. However, as in the second and fourth embodiments described above, an alloy layer is formed by using the elements injected into the polysilicon layers 405, and work function modulation may be carried out by the alloy layer.

In addition, the elements for use in work function modulation are injected into the polysilicon layers by ion implantation. However, those may be injected by another method. Although the layers into which the elements for use in work function modulation are injected are not limited to the polysilicon layers, and are preferably semiconductor layers.

C. Summary

In accordance with the sixth embodiment, in the method of manufacturing a dual metal gate electrode, a material with a low work function is precipitated directly on the gate insulating layer due to ion implantation and thermal treatment, so that work function modulation can be exactly carried out.

### (7) Seventh Embodiment

A seventh embodiment relates to an application example of the first embodiment, and is an example in which the method of manufacturing a dual metal gate electrode according to the present invention is applied to a CMOS circuit having a damascene gate structure.

A. Device Structure

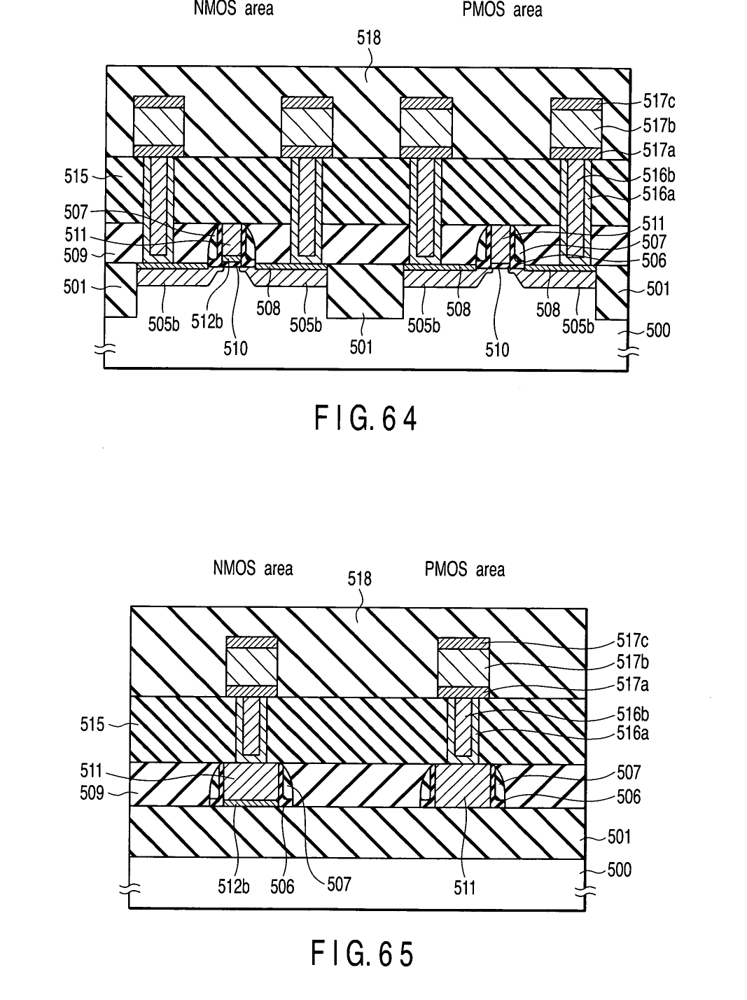

FIG. 63 is a plan view of a CMOS circuit which is formed by the method according to the seventh embodiment. FIG. 64 is a cross-sectional view taken along the line LXIV-LXIV of FIG. 63, and FIG. 65 is a cross-sectional view taken along the line LXV-LXV of FIG. 63.

An isolation layer 501 having an STI structure is arranged in a semiconductor substrate 500. As a consequence, a PMOS area in which a p-channel MOS transistor is formed and an NMOS area in which an n-channel MOS transistor is formed are formed.

The p-channel MOS transistor is configured by source/drain diffusion layers 505b, a gate insulating layer 510 on a channel between the source/drain diffusion layers 505b, and a gate electrode on the gate insulating layer 510. The gate electrode is configured by a molybdenum (Mo) layer 511 on the gate insulating layer 510.

Silicon oxide layers 506 and silicon nitride layers 507 serving as sidewalls are arranged at the sidewall portions of the molybdenum layer 511.

Nickel silicide layers 508 are formed on the surface regions of the source/drain diffusion layers 505b.

Electrodes composed of titanium nitride layers 517a and 517c, and an aluminum layer 517b are connected to the nickel silicide layers 508 and the molybdenum layer 511 serving as a gate electrode via titanium/titanium nitride 516a serving as barrier metals and tungsten 516b serving as contact plugs.

The n-channel MOS transistor is configured by source/drain diffusion layers 505b, a gate insulating layer 510 on a channel between the source/drain diffusion layers 505b, and a gate electrode on the gate insulating layer 510.

The gate electrode is configured by a gallium (Ga) precipitate layer 512b on the gate insulating layer 510, and a molybdenum layer 511 on the gallium precipitate layer 512b. Here, the molybdenum layer 511 is the same as the molybdenum layer 511 configuring the gate electrode of the p-channel MOS transistor.

Silicon oxide layers 506 and silicon nitride layers 507 serving as sidewalls are arranged at the sidewall portions of the molybdenum layer 511.

Nickel silicide layers 508 are formed on the surface regions of the source/drain diffusion layers 505b.

Electrodes composed of titanium nitride layers 517a and 517c, and an aluminum layer 517b are connected to the nickel silicide layers 508 and the molybdenum layer 511 serving as a gate electrode via titanium/titanium nitride 516a serving as barrier metals and tungsten 516b serving as contact plugs.

Both of the p-channel MOS transistor and the n-channel MOS transistor are covered with silicon oxide layers 509, 515, and 518 serving as interlayer insulating layers.

B. Method of Manufacturing Semiconductor Device

A method of manufacturing a dual metal gate electrode by work function modulation according to the seventh embodiment will be described.

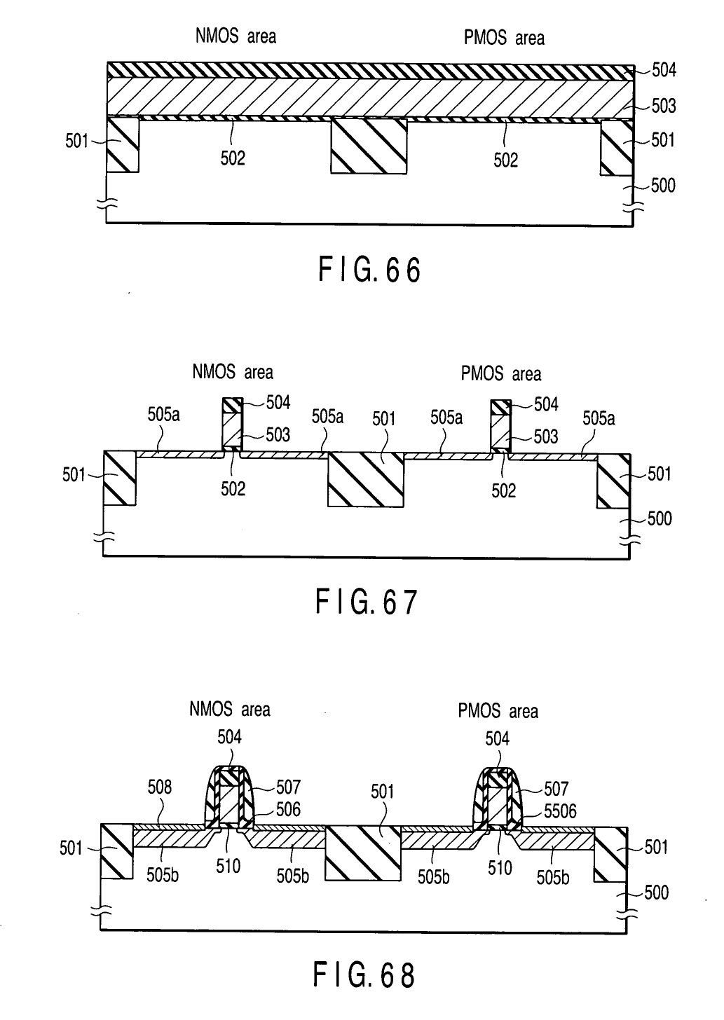

First, as shown in FIG. 66, an isolation layer 501 having an STI structure is formed in a semiconductor substrate 500, and silicon oxide layers 502 are formed by a thermal oxidation method on device regions separated by the isolation layer 501.

Then, a polysilicon layer 503 is formed so as to have a thickness of about 100 nm on the silicon oxide layers 502 by, for example, a CVD method. Next, a silicon nitride layer 504 is formed so as to have a thickness of about 50 nm on the polysilicon layer 503.

Next, as shown in FIG. 67, dummy gate electrodes are formed by patterning onto the silicon nitride layer 504 and the polysilicon layer 503 by PEP and RIE.

In addition, with the dummy gate electrodes being as masks, a p-type impurity (for example, B, BF₂, or the like) is ion-implanted into the PMOS area in a self-alignment manner, an n-type impurity (for example, P, As, or the like) is ion-implanted into the NMOS area in a self-alignment manner, and thermal treatment at about 800° C. for about five seconds is carried out, so that extension diffusion layers 505a are formed.

Next, as shown in FIG. 68, silicon oxide layers 506 and silicon nitride layers 507 are formed by, for example, a CVD method. Further, the silicon oxide layers 506 and the silicon nitride layers 507 are etched by RIE, which makes those remain as the sidewalls at the sidewall portions of the dummy gate electrodes.

Then, source/drain diffusion layers 505b are formed, with the dummy gate electrodes and the sidewalls being as masks, by carrying out ion implantation of a p-type impurity (for example, B, BF₂, or the like) into the PMOS area in a self-alignment manner, and by carrying out ion implantation of an n-type impurity (for example, P, As, or the like) into the NMOS area in a self-alignment manner.

Thereafter, nickel (Ni) layers are formed so as to have a thickness of about 10 nm on the source/drain diffusion layers 505b by, for example, sputtering. Then, silicon (Si) in the source/drain diffusion layers 505b and nickel (Ni) in the nickel layers are made to react with each other by carrying out thermal treatment at about 350° C. for about thirty seconds.

Subsequently, unreacted nickel layers are removed by using, for example, a compound liquid of sulfuric acid and hydrogen peroxide, and nickel silicide layers 508 are formed by carrying out thermal treatment at about 500° C. for about thirty seconds again.

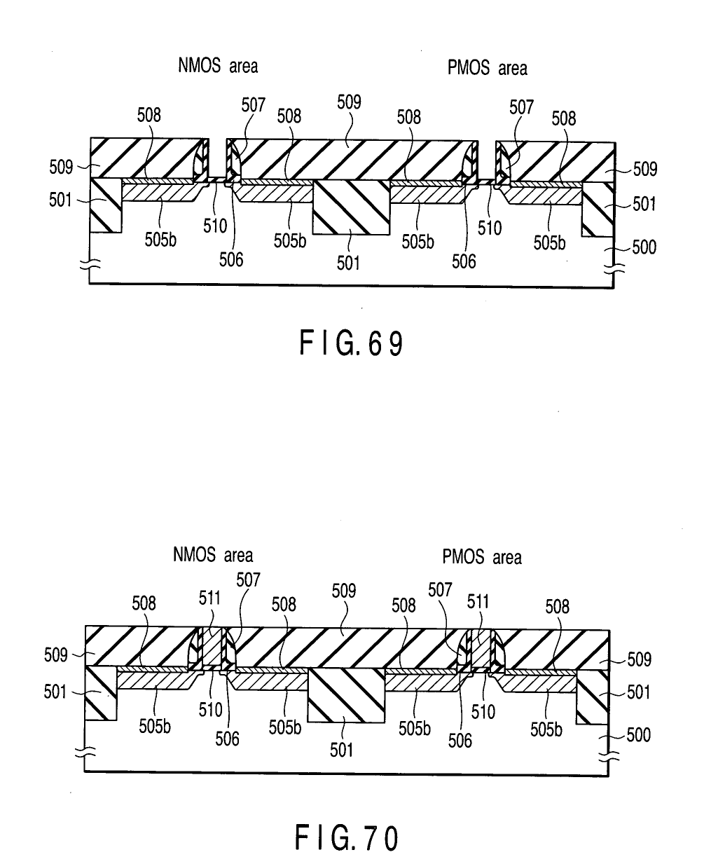

Next, as shown in FIG. 69, silicon oxide layers 509 covering the dummy gate electrodes are formed by, for example, a CVD method. Further, the silicon oxide layers 509 are grinded until the top surfaces of the dummy gate electrodes are exposed, and the surfaces thereof are planarized.

Then, grooves are formed by selectively removing the dummy gate electrodes and the silicon oxide layers 502 directly under those.

Subsequently, in the NMOS area, for example, In + ions are ion-implanted into the surface regions in the grooves of the semiconductor substrate 500, a short time thermal treatment at about 1000° C. (rapid thermal anneal) is carried out, and a channel concentration is controlled, thereby adjusting a threshold voltage of the transistor.

After the dummy gate electrodes are removed, ultra thin gate insulating layers 510 are formed in the grooves, for example, a plasma oxynitride method.

Next, as shown in FIG. 70, molybdenum (Mo) layers 511 with a work function of 4.9 eV are formed so as to have a thickness of about 150 nm by, for example, a CVD method using an organic source. Moreover, the molybdenum layers 511 are grinded by a CMP method, and those are filled into the grooves on the gate insulating layers 510.

As a result, gate electrodes configured by the molybdenum layers 511 are formed at both of the PMOS area and the NMOS area.

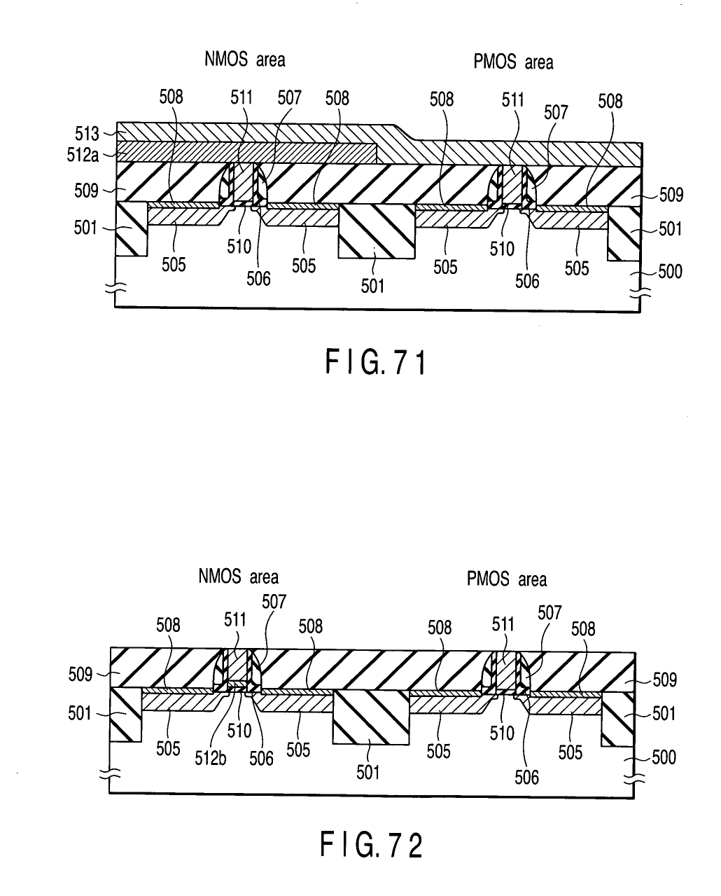

Next, as shown in FIG. 71, a GaP layer 512a is formed as a compound layer for work function modulation so as to have a thickness of 20 nm on the silicon oxide layers 509 by, for example, sputtering.

Then, the GaP layer 512a in the PMOS area is selectively removed by, for example, PEP and RIE, which makes the GaP layer 512a remain on the gate electrode of the n-channel MOS transistor in the NMOS area.

Further, a titanium nitride (TiN) layer 513 serving as a cap layer for preventing a metal from condensing is formed so as to have a thickness of about 20 nm on the silicon oxide layers 509 and the GaP layer 512a.

At this point in time, the NMOS area has a structure in which a lamination layer of GaP/TiN is arranged on the gate electrode made of Mo.

Next, as shown in FIG. 72, thermal treatment at about 500° C. for about thirty seconds is carried out in the nitrogen atmosphere, for example. As a result, the GaP layer 512a does not condense because the GaP layer 512a is covered with the titanium nitride layer 513. In addition, Ga in the GaP layer 512a diffuses via a grain boundary of the molybdenum layer 511, and is precipitated at an interface between the gate insulating layer 510 and the molybdenum layer 511 to become a gallium precipitate layer 512b.

Thereafter, the GaP layer 512a and the titanium nitride layer 513 are removed.

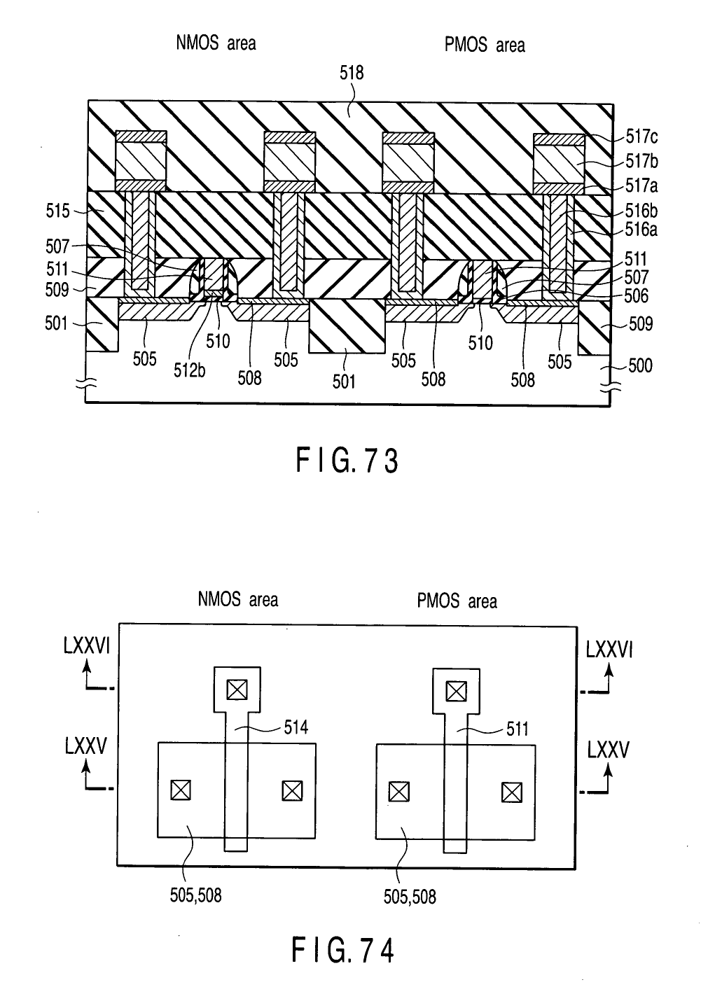

Next, as shown in FIG. 73, silicon oxide layers 515 covering the p-channel MOS transistor and the n-channel MOS transistor are formed by, for example, a CVD method. In addition, the surfaces of the silicon oxide layers 515 are planarized by, for example, a CMP method.

After contact holes coming down to the source/drain diffusion layers 505 are formed at the silicon oxide layers 509 and 515, titanium/titanium nitride 516a serving as barrier metals and tungsten 516b serving as contact plugs are formed in the contact holes.

Electrodes composed of titanium nitride layers 517a and 517c, and an aluminum layer 517b are formed on the silicon oxide layers 515, and a silicon oxide layer 518 covering those electrodes is formed on the silicon oxide layers 515.

The gate electrode of the p-channel MOS transistor formed by such a method is composed of Mo whose work function is 4.9 eV.

In addition, the gate electrode of the n-channel MOS transistor is composed of a laminated structure of Ga/Mo. Here, a threshold value of the n-channel MOS transistor depends on a work function of Ga precipitated directly on the gate insulating layer 510, and the value becomes 3.9 eV, so that work function modulation can be appropriately carried out.

Note that, as the gate insulating layer 510, not only silicon oxide, but also an oxide, a nitride, or an oxynitride of Hf, Zr, Ti, Ta, Al, Sr, Y, La and the like, or an oxide, a nitride, or an oxynitride as a compound of those elements and silicon can be used. For example, a high dielectric constant material such as a zirconium oxide and a hafnium oxide is used as the gate insulating layer 510.

C. Summary

In accordance with the seventh embodiment, in the method of manufacturing a dual metal gate electrode having a damascene gate structure, the condensation of metal is prevented, so that a material with a low work function is precipitated directly on the gate insulating layer, and work function modulation can be exactly carried out.

### (8) Eighth Embodiment

An eighth embodiment relates to an application example of the second embodiment, and is an example in which the method of manufacturing a dual metal gate electrode according to the present invention is applied to a CMOS circuit having a damascene gate structure.

A. Device Structure

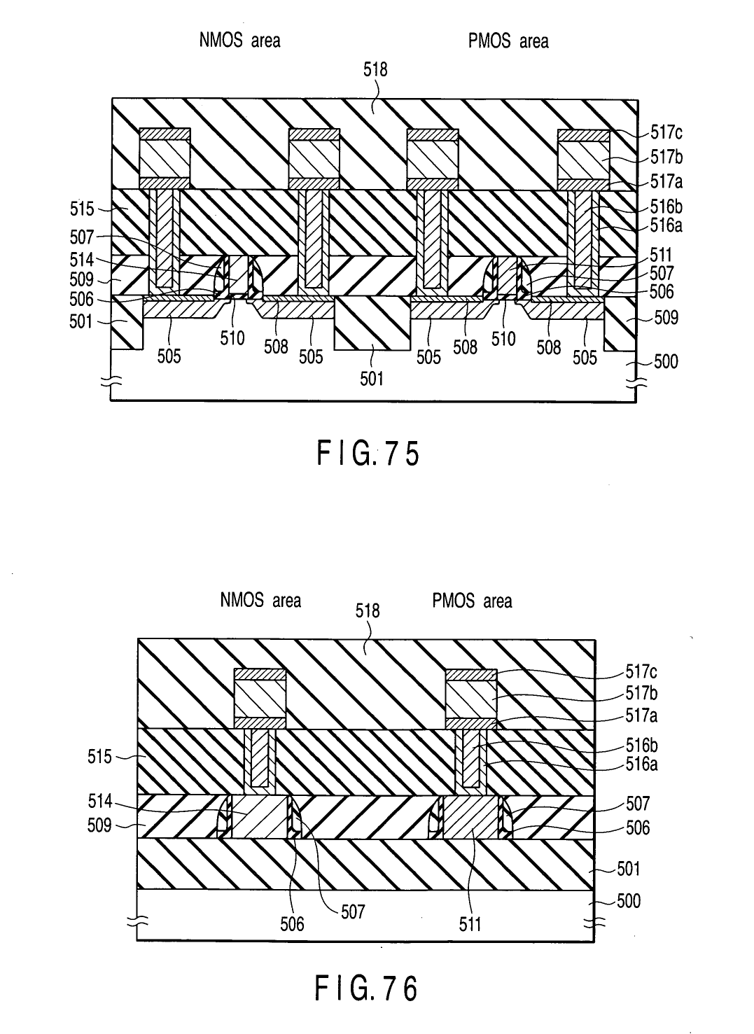

FIG. 74 is a plan view of a CMOS circuit which is formed by the method according to the eighth embodiment. FIG. 75 is a cross-sectional view taken along the line LXXV-LXXV of FIG. 74, and FIG. 76 is a cross-sectional view taken along the line LXXVI-LXXVI of FIG. 74.

An isolation layer 501 having an STI structure is arranged in a semiconductor substrate 500. As a consequence, a PMOS area in which a p-channel MOS transistor is formed and an NMOS area in which an n-channel MOS transistor is formed are formed.

The p-channel MOS transistor is configured by source/drain diffusion layers 505b, a gate insulating layer 510 on a channel between the source/drain diffusion layers 505b, and a gate electrode on the gate insulating layer 510. The gate electrode is configured by a molybdenum (Mo) layer 511 on the gate insulating layer 510.

Silicon oxide layers 506 and silicon nitride layers 507 serving as sidewalls are arranged at the sidewall portions of the molybdenum layer 511.

Nickel silicide layers 508 are formed on the surface regions of the source/drain diffusion layers 505b.

Electrodes composed of titanium nitride layers 517a and 517c, and an aluminum layer 517b are connected to the nickel silicide layers 508 and the molybdenum layer 511 serving as a gate electrode via titanium/titanium nitride 516a serving as barrier metals and tungsten 516b serving as contact plugs.

The n-channel MOS transistor is configured by source/drain diffusion layers 505b, a gate insulating layer 510 on a channel between the source/drain diffusion layers 505b, and a gate electrode on the gate insulating layer 510. The gate electrode is configured by a GaMoP layer 514 on the gate insulating layer 510.

Silicon oxide layers 506 and silicon nitride layers 507 serving as sidewalls are arranged at the sidewall portions of the GaMoP layer 514.

Nickel silicide layers 508 are formed on the surface regions of the source/drain diffusion layers 505b.

Electrodes composed of titanium nitride layers 517a and 517c, and an aluminum layer 517b are connected to the nickel silicide layers 508 and the molybdenum layer 511 serving as a gate electrode via titanium/titanium nitride 516a serving as barrier metals and tungsten 516b serving as contact plugs.

Both of the p-channel MOS transistor and the n-channel MOS transistor are covered with silicon oxide layers 509, 515, and 518 serving as interlayer insulating layers.

B. Method of Manufacturing Semiconductor Device

A method of manufacturing a dual metal gate electrode by work function modulation according to the eighth embodiment will be described.

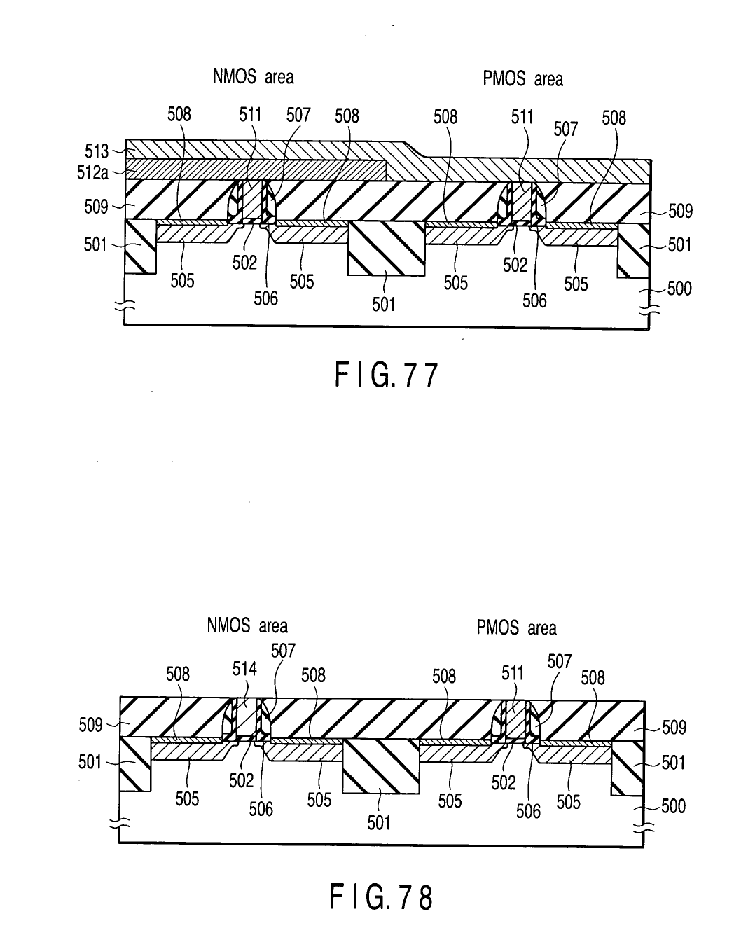

First, as shown in FIG. 77, processes until the gate electrodes composed of molybdenum (Mo) layers 511 with a work function of 4.9 eV are formed are executed in accordance with the same processes as in the seventh embodiment described above.

Thereafter, a GaP layer 512a is formed as a compound layer for work function modulation so as to have a thickness of about 20 nm on the silicon oxide layers 509 by, for example, sputtering.

Then, the GaP layer 512a in the PMOS area is selectively removed by, for example, PEP and RIE, which makes the GaP layer 512a remain on the gate electrode of the n-channel MOS transistor in the NMOS area.

In addition, a titanium nitride (TiN) layer 513 serving as a cap layer for preventing a metal from condensing is formed so as to have a thickness of about 20 nm on the silicon oxide layers 509 and the GaP layer 512a.

At this point in time, the NMOS area has a structure in which a lamination layer of GaP/TiN is arranged on the gate electrode made of Mo.

Next, as shown in FIG. 78, thermal treatment at about 400° C. for about one hour is carried out in the nitrogen atmosphere, for example. As a result, the GaP layer 512a does not condense because the GaP layer 512a is covered with the titanium nitride layer 513, and the molybdenum layer 511 chemically reacts with the GaP layer 512a to become a GaMoP layer 514.

Thereafter, the GaP layer 512a and the titanium nitride layer 513 are removed.

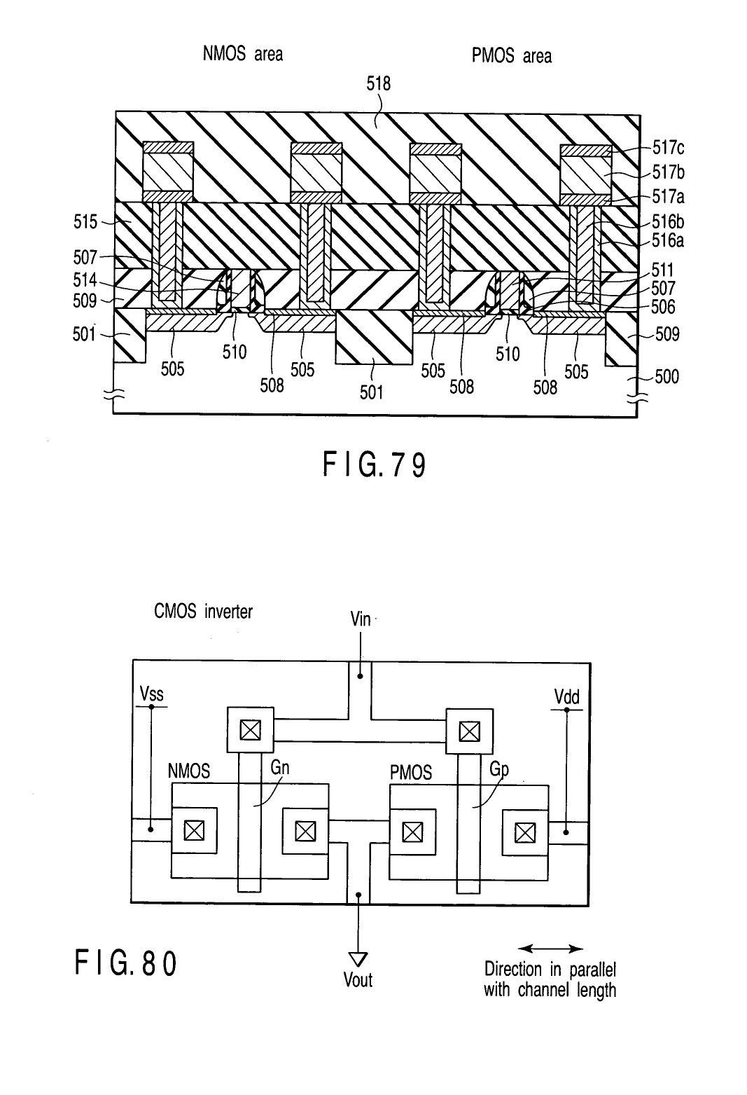

Next, as shown in FIG. 79, silicon oxide layers 515 covering the p-channel MOS transistor and the n-channel MOS transistor are formed by, for example, a CVD method. Further, the surfaces of the silicon oxide layers 515 are planarized by, for example, a CMP method.

After contact holes coming down to the source/drain diffusion layers 505 are formed at the silicon oxide layers 509 and 515, titanium/titanium nitride 516a serving as barrier metals and tungsten 516b serving as contact plugs are formed in the contact holes.

In addition, electrodes composed of titanium nitride layers 517a and 517c, and an aluminum layer 517b are formed on the silicon oxide layers 515, and a silicon oxide layer 518 covering those electrodes is formed on the silicon oxide layers 515.

The gate electrode of the p-channel MOS transistor formed by such a method is composed of Mo whose work function is 4.9 eV. In addition, the gate electrode of the n-channel MOS transistor is composed of GaMoP whose work function is 4.2 eV. In this way, work function modulation of the gate electrode of the n-channel MOS transistor is appropriately carried out.

Note that, as the gate insulating layer 510, not only silicon oxide, but also an oxide, a nitride, or an oxynitride of Hf, Zr, Ti, Ta, Al, Sr, Y, La and the like, or an oxide, a nitride, or an oxynitride as a compound of those elements and silicon can be used. For example, a high dielectric constant material such as a zirconium oxide and a hafnium oxide is used as the gate insulating layer 510.

C. Summary

In accordance with the eighth embodiment, in the method of manufacturing a dual metal gate electrode having a damascene gate structure, the condensation of metal is prevented, so that a gate electrode can be transformed into an alloy layer, and work function modulation can be exactly carried out.

### 5. APPLICATION EXAMPLES

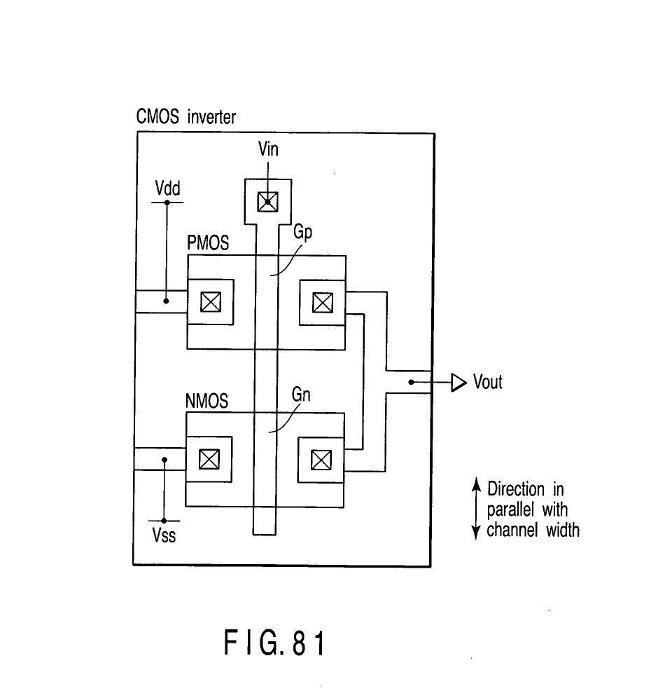

The examples of the present embodiment can be applied to a CMOS inverter circuit as shown in, for example, FIGS. 80 and 81.

In the example of FIG. 80, the p-channel MOS transistor PMOS and the n-channel MOS transistor NMOS are arranged side by side in the channel length direction, and the gate electrodes Gp and Gn are independent of each other.

In contrast thereto, in the example of FIG. 81, the p-channel MOS transistor PMOS and the n-channel MOS transistor NMOS are arranged side by side in the channel width direction, and the gate electrodes Gp and Gn are unified.

In both cases, the transistors can be formed by utilizing the method of manufacturing a metal gate electrode according to the examples of the present invention.

### 4. OTHERS

In accordance with the examples of the present invention, in the method of a metal gate electrode, the condensation of metal can be prevented, and work function modulation can be exactly carried out.

Note that, in the embodiments described above, the examples of the MOS transistors have been described. However, as the effect that a material for the gate insulating layer is not particularly limited has been described, the examples of the invention can be applied to the general MIS transistors.

In addition, the examples of the invention can be applied to a semiconductor apparatus having a metal-insulator-semiconductor (MIS) structure, for example, an MIS capacitor.

The structure of the isolation layer is not limited to an STI, and may be a field insulating layer formed by, for example, a LOCOS method.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A method of manufacturing a semiconductor device, comprising:
forming a gate insulating layer on a semiconductor substrate;
forming a first metal layer on the gate insulating layer;
forming a second metal layer including elements for use in work function modulation on the first metal layer;
forming a cap layer made of a material having a melting point higher than that of the second metal layer on the second metal layer; and
precipitating the elements at an interface between the gate insulating layer and the first metal layer by thermal treatment.

2. The method according to claim 1, wherein the second metal layer is formed in an area of an n-channel MOS transistor.

3. The method according to claim 1, wherein the first metal layer is selected from W, Pd, Pt, Ni, Co, Rh, Ir, Nb, Mo, Ta, Sb, Bi, Er, Ti, an alloy including at least one of these metals, and a nitride, a carbide, or a silicon nitride of these metals.

4. The method according to claim 1, wherein the second metal layer is selected from In, Ga, Tl, Sb, Bi, an alloy including at least one of these metals, and a III-V compound semiconductor including at least one of In and Ga.

5. A method of manufacturing a semiconductor device, comprising:
forming a gate insulating layer on a semiconductor substrate;
forming a first metal layer on the gate insulating layer;
forming a second metal layer including elements for use in work function modulation on the first metal layer;
forming a cap layer made of a material having a melting point higher than that of the second metal layer on the second metal layer; and
forming an alloy layer of the first metal layer and the second metal layer by thermal treatment.

6. The method according to claim 5, wherein the second metal layer is formed in an area of an n-channel MOS transistor.

7. The method according to claim 5, wherein the first metal layer is selected from W, Pd, Pt, Ni, Co, Rh, Ir, Nb, Mo, Ta, Sb, Bi, Er, Ti, an alloy including at least one of these metals, and a nitride, a carbide, or a silicon nitride of these metals.

8. The method according to claim 5, wherein the second metal layer is selected from In, Ga, Tl, Sb, Bi, an alloy including at least one of these metals, and a III-V compound semiconductor including at least one of In and Ga.

9. A method of manufacturing a semiconductor device, comprising:
forming a gate insulating layer on a semiconductor substrate;
forming a metal layer on the gate insulating layer;
forming a compound layer including elements for use in work function modulation on the metal layer; and
precipitating the elements at an interface between the gate insulating layer and the metal layer by thermal treatment.

10. The method according to claim 9, wherein the compound layer is formed in an area of an n-channel MOS transistor.

11. The method according to claim 9, wherein the elements are selected from a group consisting of In, Ga, Tl, Sb, and Bi.

12. A method of manufacturing a semiconductor device, comprising:
forming a gate insulating layer on a semiconductor substrate;
forming a metal layer on the gate insulating layer;
forming a compound layer including elements for use in work function modulation on the metal layer; and
forming an alloy layer of the metal layer and the compound layer by thermal treatment.

13. The method according to claim 12, wherein the compound layer is formed in an area of an n-channel MOS transistor.

14. The method according to claim 12, wherein the elements are selected from a group consisting of In, Ga, Tl, Sb, and Bi.

15. A method of manufacturing a semiconductor device, comprising:
forming a gate insulating layer on a semiconductor substrate;
forming a metal layer on the gate insulating layer;
forming a semiconductor layer on the metal layer;
injecting elements for use in work function modulation into the semiconductor layer; and
precipitating the elements at an interface between the gate insulating layer and the metal layer by thermal treatment.

16. The method according to claim 15, wherein the elements are injected into an area of an n-channel MOS transistor.

17. The method according to claim 15, wherein the elements are selected from a group consisting of In, Ga, Tl, Sb, and Bi.

18. A method of manufacturing a semiconductor device, comprising:
forming a gate insulating layer on a semiconductor substrate;
forming a metal layer on the gate insulating layer;
forming a semiconductor layer on the metal layer;
injecting elements for use in work function modulation into the semiconductor layer; and
forming an alloy layer by making the elements react with the metal layer by thermal treatment.

19. The method according to claim 18, wherein the elements are injected into an area of an n-channel MOS transistor.

20. The method according to claim 18, wherein the elements are selected from a group consisting of In, Ga, Tl, Sb, and Bi.
